(19) United States
(12) Patent Application Publication
(10) Pub. No.: US 2025/0255156 A1
(43) Pub. Date: Aug. 7, 2025

(54) DISPLAY APPARATUS

(71) Applicant: LG Display Co., Ltd., Seoul (KR)

(72) Inventors: Hyemin Park, Paju-si (KR); Donggu Kim, Paju-si (KR); Sejong Seong, Paju-si (KR); Inae Choi, Paju-si (KR); Taehyeon Kim, Paju-si (KR)

(73) Assignee: LG Display Co., Ltd., Seoul (KR)

(21) Appl. No.: 18/927,409

(22) Filed: Oct. 25, 2024

(30) Foreign Application Priority Data
Feb. 6, 2024 (KR) 10-2024-0018330

(51) Int. Cl. H10K 59/80; H10K 59/124; H10K 59/38

(52) U.S. Cl. CPC H10K 59/878; H10K 59/124; H10K 59/80521; H10K 59/38

(57) ABSTRACT

A display apparatus including a substrate including a plurality of pixels, each pixel having a plurality of sub-pixels and non-light emission areas between the sub-pixel; a pattern portion disposed on the substrate; and a reflective portion disposed on the pattern portion. In addition, the pattern portion includes a first inclined pattern portion inclining at a first angle with respect to an upper surface of the substrate; and a second inclined pattern portion inclining at a second angle with respect to the upper surface of the substrate. Also, the reflective portion includes a first inclined reflective portion disposed on the first inclined pattern portion; and a second inclined reflective portion disposed on the second inclined pattern portion

### CROSS-REFERENCE TO RELATED APPLICATION

This application claims priority to Korean Patent Application No. 10-2024-0018330, filed in the Republic of Korea on Feb. 6, 2024, the entire contents of which are hereby expressly incorporated by reference into the present application.

### BACKGROUND

### Field of the Invention

The present disclosure relates to a display apparatus displaying images.

### Discussion of the Related Art

Because an organic light emitting display apparatus has a high response speed and low power consumption and self-emits light without requiring a separate light source unlike a liquid crystal display apparatus, there is no problem in a viewing angle and thus the organic light emitting display apparatus has received attention as a next-generation flat panel display apparatus. Such a display apparatus displays an image through light emission of a light emitting element layer that includes a light emitting layer interposed between two electrodes.

In addition, light extraction efficiency of the display apparatus is reduced as some of light emitted from the light emitting element layer is not emitted to the outside due to total reflection on the interface between multiple layers inside a display panel.

### SUMMARY

An aspect of the present disclosure is directed to providing a display apparatus in which a light extraction efficiency of light emitted from a light emitting element layer can be improved.

Further, an aspect of the present disclosure is directed to providing a display apparatus in which overall power consumption can be reduced through light extraction from a non-light emission area.

Further, an aspect of the present disclosure is directed to providing a display apparatus capable of maximizing light extraction efficiency.

The problems to be solved by the examples of the present disclosure are not limited to those mentioned above, and other problems not mentioned will be apparent to one of ordinary skill in the art to which the technical spirits of the present disclosure belong from the following description.

A display apparatus comprising: a substrate including a plurality of pixels having a plurality of sub-pixels; a pattern portion disposed on the substrate to be concave in a non-light emission area between the plurality of the sub-pixels; and a reflective portion disposed on the pattern portion, wherein the pattern portion includes: a first inclined pattern portion disposed to have a first angle with respect to the upper surface of the substrate; and a second inclined pattern portion disposed between the first inclined pattern portion and the substrate and disposed to have a second angle with respect to an upper surface of the substrate.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a display apparatus according to one embodiment of the present disclosure.

FIG. 2 is a schematic plan view of one pixel illustrated in FIG. 1.

FIG. 3 is a schematic cross-sectional view of the line I-I′ shown in FIG. 2.

FIG. 4 is a schematic cross-sectional view of the line II-II′ shown in FIG. 2.

FIG. 5 is a schematic cross-sectional view of the line III-III′ shown in FIG. 2.

FIG. 6 is a schematic enlarged cross-sectional view of portion A shown in FIG. 3

FIG. 7 is a schematic enlarged cross-sectional view illustrating a display apparatus according to another embodiment of the present disclosure, as another example of the portion A shown in FIG. 3.

FIG. 8A is an image illustrating light extraction characteristics of a display apparatus according to a comparative example.

FIG. 8B is an image illustrating light extraction characteristics of a display apparatus according to another comparative example.

FIG. 8C is an image illustrating light extraction characteristics of a display apparatus according to another embodiment of the present disclosure.

FIG. 9 is a graph depicting light intensity as a function of wavelength for a display apparatus according to another embodiment of the present disclosure compared to a display apparatus according to a comparative example.

FIG. 10 is a schematic enlarged cross-sectional view illustrating a display apparatus according to another embodiment of the present disclosure, as another example of the portion A shown in FIG. 3.

### DETAILED DESCRIPTION OF THE DISCLOSURE

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout.

In a case where ‘comprise’, ‘have’, and ‘include’ described in the present specification are used, another part can be added unless ‘only˜’ is used. The terms of a singular form can include plural forms unless referred to the contrary. In construing an element, the element is construed as including an error range although there is no explicit description.

In describing a position relationship, for example, when a position relation between two parts is described as ‘on˜’, ‘over˜’, ‘under˜’, and ‘next˜’, one or more other parts can be disposed between the two parts unless ‘just’ or ‘direct’ is used. In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and can have broader directionality within the range that elements of the present disclosure can act functionally. The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship.

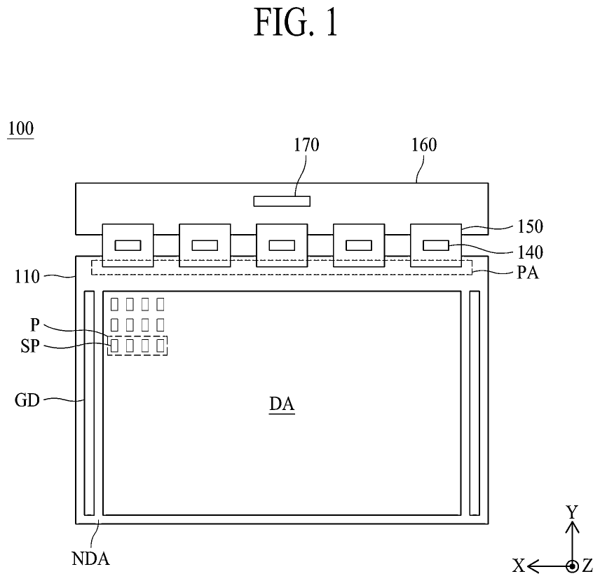

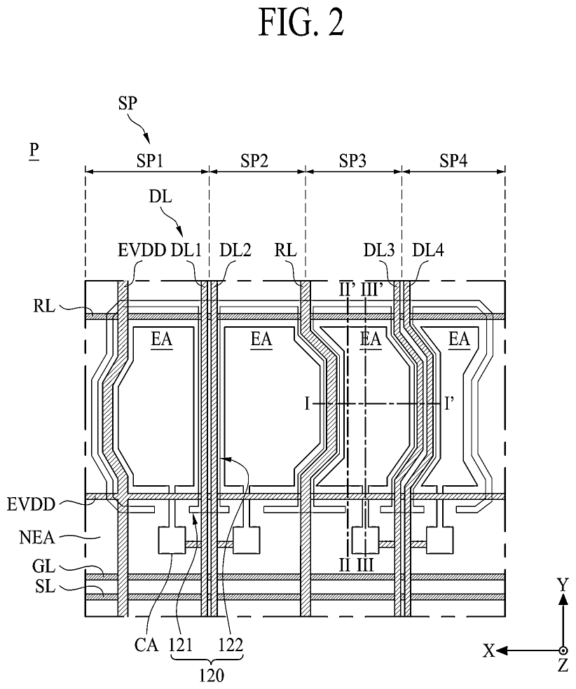

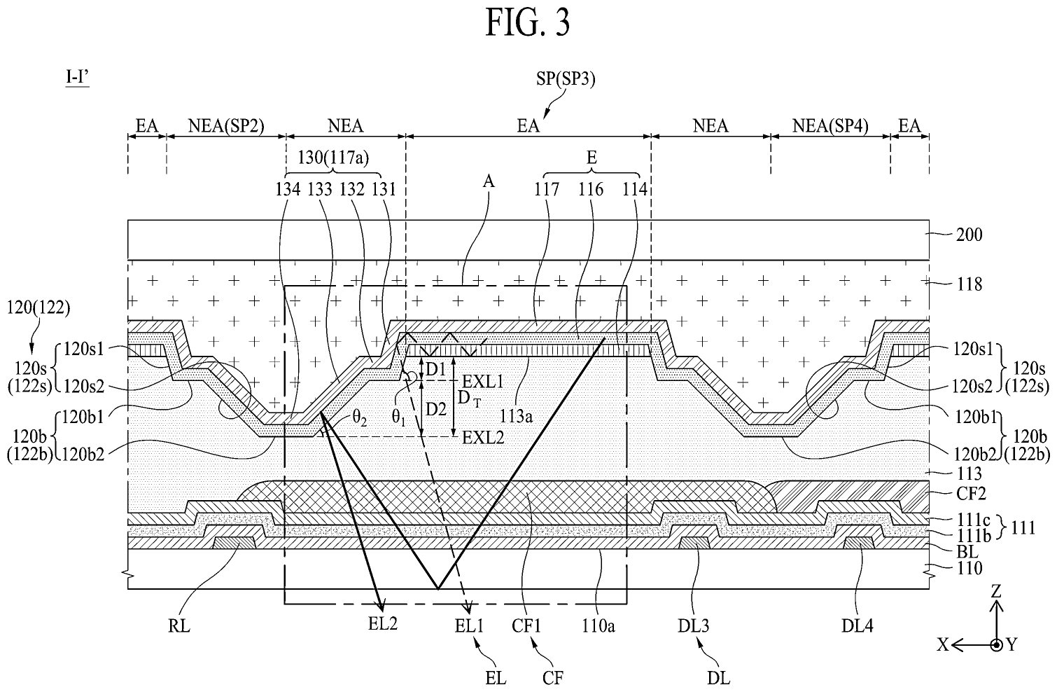

Hereinafter, the preferred embodiments of the present disclosure will be described in detail with reference to the accompanying drawings. In particular, FIG. 1 is a schematic plan view of a display apparatus according to one embodiment of the present disclosure, FIG. 2 is a schematic plan view of one pixel illustrated in FIG. 1, and FIG. 3 is a schematic cross-sectional view of the line I-I′ shown in FIG. 2.

Referring to FIGS. 1 to 3, a display apparatus 100 according to one embodiment of the present disclosure includes a substrate 110 with pixels including a plurality of sub-pixels SPs, a pattern portion 120 disposed on the substrate 110 and concavely formed in a non-light emission area NEA between the plurality of sub-pixels SPs, and a reflective portion 130 disposed on the pattern portion 120.

The pattern portion 120 can be formed on an overcoat layer 113 disposed on the substrate 110. In more detail, the pattern portion 120 according to one example can be concavely formed in the non-light emission area NEA by patterning and removing the overcoat layer 113 between a plurality of sub-pixels SPs. After the pattern portion 120 is formed to be concave, an organic light emitting layer 116 and a reflective electrode 117 can be sequentially deposited on the entire surface in a subsequent process. Thus, as shown in FIG. 3, the organic light emitting layer 116 and the reflective electrode 117 can be formed to be concave in the non-light emission area NEA along the profile of the pattern portion 120. Here, the reflective electrode 117 formed to be concave in the non-light emission area NEA can be the reflective portion 130. Also, the pattern portion 120 according to one example can include a first inclined pattern portion 120s1 and a second inclined pattern portion 120s2. In addition, the pattern portion 120 can further include a first flat pattern portion 120b1 and a second flat pattern portion 120b2. The first inclined pattern portion 120s1 and the second inclined pattern portion 120s2 can be included on an inclined surface 120s of the pattern portion 120. Further, the first flat pattern portion 120b1 and the second flat pattern portion 120b2 can be included on a flat surface 120b of the pattern portion 120.

As shown, the first inclined pattern portion 120s1 can be disposed at a first angle θ1 with respect to the upper surface 110a of the substrate 110. For example, the upper surface 110a of the substrate 110 can be disposed in a direction parallel to a first direction (X-axis direction). In one example, the first direction (X-axis direction) can be a horizontal direction with respect to FIG. 1, and the horizontal direction can be a direction in which the gate wiring extends. Also, the second direction (Y-axis direction), according to one example, is a direction intersecting the first direction (X-axis direction) and can be a perpendicular direction with respect to FIG. 1. In addition, the perpendicular direction can be a direction in which the data wiring extends. A third direction (Z-axis direction) according to one example can be a direction intersecting each of the first direction (X-axis direction) and the second direction (Y-axis direction), and can be a thickness direction of the display apparatus 100.

As shown in FIG. 3, the first extension line EXL1 is disposed in a direction parallel to the upper surface 110a of the substrate 110, so that the first inclined pattern portion 120s1 can be represented as being disposed at the first angle θ₁ with respect to the first extension line EXL1. Also, the first extension line EXL1 can refer to an imaginary line extending in the first direction (X-axis direction) from a point where the first inclined pattern portion 120s1 and the first flat pattern portion 120b1 contact. As the first inclined pattern portion 120s1 is disposed at the first angle θ₁ with respect to the upper surface 110a of the substrate 110, the organic light emitting layer 116 and the reflective electrode 117 (or the reflective portion 130) formed on the first inclined pattern portion 120s1 can also be disposed at the first angle θ₁ with respect to the upper surface 110a (or the first extension line EXL1) of the substrate 110.

In addition, the second inclined pattern portion 120s2 is disposed between the first inclined pattern portion 120s1 and the substrate 110 and can be disposed at a second angle θ2 with respect to the upper surface 110a of the substrate 110. As shown in FIG. 3, the second extension line EXL2 is disposed in a direction parallel to the upper surface 110a of the substrate 110, so the second inclined pattern portion 120s2 can be represented as being disposed at the second angle θ₂ with respect to the second extension line EXL2. In addition, the second extension line EXL2 can refer to an imaginary line extending in the first direction (X-axis direction) from a point where the second inclined pattern portion 120s2 and the second flat pattern portion 120b2 contact. Also, the second extension line EXL2 can be spaced apart from and parallel to the first extension line EXL1. As the second inclined pattern portion 120s2 is disposed at the second angle θ₂ with respect to the upper surface 110a of the substrate 110, the organic light emitting layer 116 and the reflective electrode 117 (or the reflective portion 130) formed on the second inclined pattern portion 120s2 can also be disposed at the second angle θ2 with respect to the upper surface 110a (or the second extension line EXL2) of the substrate 110.

On the other hand, the second inclined pattern portion 120s2 can be connected via the first flat pattern portion 120b1, which is flat and extending long in the first direction (X-axis direction). Thus, as shown in FIG. 3, the second inclined pattern portion 120s2 can be spaced apart from the first inclined pattern portion 120s1 in the first direction (X-axis direction). Because the second inclined pattern portion 120s2 is disposed lower than the first inclined pattern portion 120s1 in the third direction (Z-axis direction), the second inclined pattern portion 120s2 can be disposed closer to the upper surface 110a of the substrate 110 than the first inclined pattern portion 120s1.

In addition, the first flat pattern portion 120b1 according to an example can be flatly provided connecting the first inclined pattern portion 120s1 and the second inclined pattern portion 120s2. Accordingly, the first inclined pattern portion 120s1 and the second inclined pattern portion 120s2 can be spaced apart in the first direction (X-axis direction) by a length of the first flat pattern portion 120b1.

Further, the second flat pattern portion 120b2, according to an example, can be spaced apart from the first flat pattern portion 120b1 and can be connected to the second inclined pattern portion 120s2. As shown in FIG. 3, the second flat pattern portion 120b2 can be flat. Also, the second flat pattern portion 120b2 can be disposed lowest in the pattern portion 120, and thus can be referred as a bottom surface of the pattern portion 120. The second flat pattern portion 120b2 can also be spaced apart from the first flat pattern portion 120b1 by a length (or component) of the first direction (X-axis direction) of the second inclined pattern portion 120s2. Further, the second flat pattern portion 120b2 can be disposed spaced apart from the first flat pattern portion 120b1 by a length (or component) of the third direction (Z-axis direction) of the second inclined pattern portion 120s2. Alternatively, the second flat pattern portion 120b2 can be disposed spaced apart from the first flat pattern portion 120b1 by a thickness (or second thickness D2) of the overcoat layer 113 in which the second inclined pattern portion 120s2 is formed.

In addition, the width of the pattern portion 120 according to one example can decrease in the direction from the reflective portion 130 toward the substrate 110. Thus, the width of the pattern portion 120 surrounded by the second inclined pattern portion 120s2 can be narrower than the width of the pattern portion 120 surrounded by the first inclined pattern portion 120s1. In other words, the pattern portion 120 can be provided in the form of a bowl in which the width of the groove narrows as it goes downward in the third direction (Z-axis direction).

In the display apparatus 100 according to one embodiment of the present disclosure, the first inclined pattern portion 120s1 and the second inclined pattern portion 120s2 can be disposed in the non-light emission area NEA. Therefore, the display apparatus 100 can reflect light emitted from the organic light emitting layer 116 and directed toward the adjacent sub-pixel SP through the reflective portion 130 disposed on the first inclined pattern portion 120s1 and the second inclined pattern portion 120s2, so that the light extraction efficiency can be improved.

Furthermore, because the display apparatus 100 can extract light from the non-light emission area NEA that is a periphery of the light emission area EA through the reflective portion 130 disposed on the pattern portion 120 (or the first inclined pattern portion 120s1 and the second inclined pattern portion 120s2), compared to a display apparatus without the pattern portion 120 and/or the reflective portion 130, the same luminous efficiency can be achieved with lower power, and the luminous efficiency can be further improved, resulting in lower overall power consumption. Furthermore, the display apparatus 100 can have the same light emitting efficiency with lower power, thus the lifetime of the light emitting element layer E (or organic light emitting layer 116) (shown in FIG. 3) can be improved.

Referring to FIG. 3, in the display apparatus 100 according to one embodiment of the present disclosure, reflective light EL reflected by the reflective portion 130 can include a first reflected light EL1 (or WG mode extracted light EL1) and a second reflected light EL2 (or substrate mode extracted light EL2). In more detail, the first reflected light EL1 (or WG mode extracted light EL1) is emitted from the organic light emitting layer 116, wave guided through being totally reflected from interfaces between the pixel electrode 114 and the overcoat layer 113, and the reflective electrode 117, then reflected from the reflective portion 130 and directed to the substrate 110. In addition, the second reflected light (EL2) (or substrate mode extracted light (EL2)) is emitted from the organic light emitting layer 116, firstly reflected from the interface between the lower surface of the substrate 110 and outside air, then secondly reflected from the reflective portion 130 and directed to the substrate 110. In FIG. 3, the first reflected light EL1 shown as a dash line and the second reflected light EL2 shown as a solid line can be reflected light that is reflected by the reflective portion 130 and extracted to the outside of the substrate 110.

As shown in FIG. 3, the first reflective light EL1 according to an example can be reflected by the reflective portion 130 and emitted from the light emission area EA. Also, the second reflected light EL2 can be emitted at a location spaced apart from the light emission area EA. For example, the second reflected light EL2 can be emitted from the non-light emission area NEA or a periphery of the light emission area EA (or a periphery area). However, the first reflected light EL1 can be emitted toward the substrate 110 from a location (or non-light emission area NEA) spaced apart from the light emission area EA, and the second reflected light EL2 can be emitted from the light emission area EA.

Hereinafter, he display apparatus 100 according to an embodiment of the present specification will be described in more detail with reference to FIGS. 1 and 2. Referring to FIGS. 1 and 2, the display apparatus 100 can include a display panel having a gate driver GD, a source drive integrated circuit (hereinafter, referred to as “IC”) 140, a flexible film 150, a circuit board 160, and a timing controller 170.

The display panel can include a substrate 110 and an opposite substrate 200 (shown in FIG. 3). In more detail, the substrate 110 can include a thin film transistor, and can be a transistor array substrate, a lower substrate, a base substrate, or a first substrate. The substrate 110 can also be a transparent glass substrate or a transparent plastic substrate. As shown, the substrate 110 can include a display area DA and a non-display area NDA.

In addition, the display area DA is an area where an image is displayed, and can be a pixel array area, an active area, a pixel array unit, a display unit, or a screen. For example, the display area DA can be disposed at a central portion of the display panel. The display area DA can include a plurality of pixels P.

Also, the opposite substrate 200 can encapsulate (or seal) the display area DA disposed on the substrate 110. For example, the opposite substrate 200 can be bonded to the substrate 110 via an adhesive member (or clear glue). The opposite substrate 200 can also be an upper substrate, a second substrate, or an encapsulation substrate. Further, the opposite substrate 200 can comprise a metal layer that is magnetic, such as Invar, SUS, or the like. Alternatively, the opposite substrate 200 can be composed of multiple layers, such as a metal layer for good heat dissipation, such as Aluminum, an organic adhesive layer for adhesion, and an organic protective layer that is thicker than the metal layer for improved encapsulating performance.

In addition, the gate driver GD supplies gate signals to the gate lines in accordance with the gate control signal input from the timing controller 170. In more detail, the gate driver GD can be formed on one side of the light emission area EA or in the non-light emission area NEA outside both sides of the light emission area EA in a gate driver in panel (GIP) method, as shown in FIG. 1.

Also, the non-display area NDA is an area on which an image is not displayed, and can be a peripheral area, a signal supply area, an inactive area or a bezel area. The non-display area NDA can be configured to be in the vicinity of the display area DA. That is, the non-display area NDA can be disposed to surround the display area DA.

A pad area PA can also be disposed in the non-display area NDA. The pad area PA can supply a power source and/or a signal for outputting an image to the pixel P provided in the display area DA. Referring to FIG. 1, the pad area PA can be provided above the display area DA.

Further, the source drive IC 140 receives digital video data and a source control signal from the timing controller 170. The source drive IC 140 also converts the digital video data into analog data voltages according to the source control signal and supplies the analog data voltages to the data lines. When the source drive IC 140 is manufactured as a driving chip, the source drive IC 140 can be packaged in the flexible film 150 in a chip on film (COF) method or a chip on plastic (COP) method.

Pads, such as data pads, can further be formed in the non-display area NDA of the display panel. Lines connecting the pads with the source drive IC 140 and lines connecting the pads with lines of the circuit board 160 can be formed in the flexible film 150. Further, the flexible film 150 can be attached onto the pads by using an anisotropic conducting film, whereby the pads can be connected with the lines of the flexible film 150.

In addition, the circuit board 160 can be attached to the flexible films 150, and a plurality of circuits implemented as driving chips can be packaged in the circuit board 160. For example, the timing controller 170 can be packaged in the circuit board 160. The circuit board 160 can also be a printed circuit board or a flexible printed circuit board.

Further, the timing controller 170 receives the digital video data and a timing signal from an external system board through a cable of the circuit board 160. The timing controller 170 also generates a gate control signal for controlling an operation timing of the gate driver GD and a source control signal for controlling the source drive ICs 140 based on the timing signal. Further, the timing controller 170 supplies the gate control signal to the gate driver GD, and supplies the source control signal to the source drive ICs 140.

Referring to FIGS. 2 and 3, the substrate 110 according to an example can include the light emission area EA and the non-light emission area NEA. In particular, the light emission area EA can correspond to an area from which light is emitted. Further, a light emitting element layer E, which includes a pixel electrode 114, an organic light emitting layer 116 and a reflective electrode 117, can be disposed in the light emission area EA. When an electric field is formed between the pixel electrode 114 and the reflective electrode 117, the organic light emitting layer 116 in the light emission area EA can emit light.

As shown in FIG. 3, an optical path of a portion of the light emitted by the organic light emitting layer 116 can be formed toward an adjacent sub-pixel (or non-emitting sub-pixel) through the organic light emitting layer 116 and the pixel electrode 114, which are disposed between the reflective electrodes 117 and the upper surface 113a of the overcoat layer 113, and/or through the overcoat layer 113. In addition, the display apparatus 100 can have the reflective portion 130 disposed between the sub-pixels SPs, and thus the reflective portion 130 can reflect light directing to the adjacent sub-pixels toward the non-light emission area NEA or the light emission area EA or toward the emitting sub-pixels. Accordingly, the display apparatus 100 can improve the light extraction efficiency of the emitting sub-pixel by extracting the light directed toward the adjacent sub-pixel through the reflective portion 130. Furthermore, the display apparatus 100 can be prevented from color mixing due to the reflective portion 130 disposed between the sub-pixels SP. As a result, the display apparatus 100 can have an overall improved light efficiency while preventing color mixing with adjacent sub-pixels (or adjacent, non-emitting sub-pixels) through the reflective portion 130 disposed on the pattern portion 120 of the non-light emission area NEA.

Referring back to FIG. 2, the light emission area EA according to an example can include gate lines, data lines, pixel driving power lines, and a plurality of pixels P. Each of the plurality of pixels P can include a plurality of subpixels SP that can be defined by the gate lines and the data lines.

Also, at least four subpixels, which are provided to emit different colors and disposed to be adjacent to one another, among the plurality of subpixels SP can constitute one pixel P (or unit pixel). One pixel P can include, but is not limited to, a red subpixel, a white subpixel, a blue subpixel and a green subpixel. One pixel P can also include three subpixels SP provided to emit light of different colors and disposed to be adjacent to one another. For example, one pixel P can include a red subpixel, a green subpixel and a blue subpixel.

Each of the plurality of subpixels SP includes a thin film transistor and a light emitting element layer E connected to the thin film transistor. Each of the plurality of subpixels can also include a light emitting layer (or an organic light emitting layer) interposed between the pixel electrode and the reflective electrode.

Further, the light emitting layers disposed in each of the plurality of sub-pixels SP can emit white light in common. Because the light emitting layer of each of the plurality of sub-pixels SP emits white light in common, each of the red sub-pixel, the green sub-pixel, and the blue sub-pixel can include a color filter CF (or wavelength conversion member CF) that converts the white light to the respective colored light. In this instance, the white sub-pixel does not include a color filter.

In addition, the area with the red color filter can be a red sub-pixel or a first sub-pixel, the area without the color filter can be a white sub-pixel or a second sub-pixel, the area with the blue color filter can be a blue sub-pixel or a third sub-pixel, and the area with the green color filter can be a green sub-pixel or a fourth sub-pixel. Further, each of the subpixels SP supplies a predetermined current to the organic light emitting element in accordance with a data voltage of the data line when a gate signal is input from the gate line by using the thin film transistor. Therefore, the light emitting layer of each of the subpixels can emit light with a predetermined brightness in accordance with the predetermined current.

In addition, the plurality of subpixels SP according to one example can be disposed to be adjacent to each other in a first direction (X-axis direction). In more detail, the plurality of subpixels SP can include a first subpixel SP1, a second subpixel SP2, a third subpixel SP3 and a fourth subpixel SP4 arranged adjacent to each other in the first direction (X-axis direction). For example, the first subpixel SP1 can be a red subpixel, the second subpixel SP2 can be a white subpixel, the third subpixel SP3 can be a blue subpixel and the fourth subpixel SP4 can be a green subpixel, but is not limited thereto. However, the arrangement order of the first subpixel SP1, the second subpixel SP2, the third subpixel SP3 and the fourth subpixel SP4 can be changed.

Also, each of the first to fourth subpixels SP1 to SP4 can include a light emission area EA and a circuit area CA. The light emission area EA can be disposed at one side (or an upper side) of a subpixel area, and the circuit area CA can be disposed at the other side (or a lower side) of the subpixel area. For example, the circuit area CA can be disposed at one side (or the lower side) of the light emission area EA based on the second direction (Y-axis direction). The light emission area EA of each of the first to fourth sub-pixels SP1 to SP4 can also have the same size (or area) or different sizes (or areas) from each other.

In addition, the first to fourth subpixels SP1 to SP4 can be disposed to be adjacent to one another along the first direction (X-axis direction). For example, two data lines DL extended long along the second direction (Y-axis direction) can be disposed in parallel with each other between the first subpixel SP1 and the second subpixel SP2 and between the third subpixel SP3 and the fourth subpixel SP4. Also, a pixel power line EVDD (or branch wiring of the pixel power line) extended along the first direction (X-axis direction) can be disposed between the light emission area EA and the circuit area CA of each of the first to fourth subpixels SP1 to SP4. Further, the gate line GL and a sensing line SL can be disposed below the circuit area CA. The pixel power line EVDD (shown in FIG. 2) extended along the second direction (Y-axis direction) can also be disposed at one side of the first subpixel SP1 or the fourth subpixel SP4. A reference line RL extended long along the second direction (Y-axis direction) can be disposed between the second subpixel SP2 and the third subpixel SP3. Further, the reference line RL can be used as a sensing line for sensing a change of characteristics of a driving thin film transistor and/or a change of characteristics of the light emitting element layer, which is disposed in the circuit area, from the outside in a sensing driving mode of the pixel P. In one example, the data lines DL are for supplying data signals to each of the plurality of the sub-pixels SP to drive each of the plurality of the sub-pixels SP. For example, the data lines DL can include a first data line DL1 for driving a first sub-pixel SP1, a second data line DL2 for driving a second sub-pixel SP2, a third data line DL3 for driving a third sub-pixel SP3, and a fourth data line DL4 for driving a fourth sub-pixel SP4.

In the display apparatus 100 according to one embodiment of the present disclosure, the data lines can be disposed not to overlap the light emission area EA. For example, the third data line DL3 can be arranged such that it does not overlap the light emission area EA. Thus, the third data line DL3 does not overlap (or is not interfered with) light emitted from the light emission area EA, and therefore a decrease in light extraction efficiency can be prevented. In addition, the first data line DL1, the second data line DL2, and the fourth data line DL4, like the third data line DL3, can be disposed in the non-light emission area NEA of the corresponding sub-pixel no to be overlapped the light emission area EA of the corresponding sub-pixel in the third direction (Z-axis direction). Thus, the data lines DL1, DL2, DL3, DL4 can have a structural feature that do not overlap the light emission area EA but overlap the non-light emission area NEA. On the other hand, each of the pixel power line EVDD and the reference line RL can be disposed in the non-light emission area NEA so as not to obscure (or interfere with) light emitted from the light emission area EA, such as the data lines described above.

In the display apparatus 100 according to one embodiment of the present disclosure, each of the plurality of the sub-pixels SP can include the light emission area EA disposed adjacent to the non-light emission area NEA. As shown in FIG. 3, the reflective portion 130 can be spaced apart from the light emission area EA. This is because if the reflective portion 130 is not spaced apart from the light emission area and is disposed adjacent to the light emission area or overlapped with the light emission area, the light emitted from the light emission area EA is not able to be reflected by the reflective portion 130.

Thus, the reflective portion 130 is spaced apart from the light emission area EA, such that light directed to an adjacent sub-pixel (e.g., the second sub-pixel SP2) among the light emitted from the light emission area EA can be reflected by the reflective portion 130, thereby improving light extraction efficiency. On the other hand, as shown in FIG. 3, the light emission area EA is an area defined by the pixel electrode 114 disposed on the overcoat layer 113, so the reflective portion 130 can be spaced apart from the pixel electrode 114. In contrast, because the pixel electrode 114 is formed on the upper surface 113a of the overcoat layer 113, the first inclined pattern portion 120s1 of the pattern portion 120 can be disposed adjacent to the pixel electrode 114. For example, the first inclined pattern portion 120s1 can be disposed adjacent to an edge of a lower surface of the pixel electrode 114. Also, the second inclined pattern portion 120s2 can be spaced apart from the first inclined pattern portion 120s1 in the first direction (X-axis direction), and thus can be spaced apart from the pixel electrode 114.

Further, the overcoat layer 113 (or the first overcoat layer) on which the first inclined pattern portion 120s1 is formed can be provided to have a first thickness D1. Also, the overcoat layer 113 (or the second overcoat layer) in which the second inclined pattern portion 120s2 is formed can be provided to have a second thickness D2. In FIG. 3, the first thickness D1 can be provided to be thinner than the second thickness D2, but is not limited thereto, and the first thickness D1 can be provided to be equal to or thicker than the second thickness D2 depending on the optimal design for improving the light extraction efficiency. A sum of the first thickness D1 and the second thickness D2 can also be the total thickness DT of the overcoat layer 113 on which the first inclined pattern portion 120s1 and the second inclined pattern portion 120s2 are disposed.

Referring again to FIG. 3, the display apparatus 100 can be provided with the first angle θ₁ equal to or different from the second angle θ₂. For example, when the first angle θ1 is equal to the second angle θ₂, the reflective portion 130 on the first inclined pattern portion 120s1 and the reflective portion 130 on the second inclined pattern portion 120s2 can be disposed at the same angle with respect to the upper surface 110a of the substrate 110 to reflect light directed to an adjacent sub-pixel toward the emitting sub-pixel. In another example, if the first angle θ₁ is different from the second angle θ₂, the reflective portion 130 on the first inclined pattern portion 120s1 and the reflective portion 130 on the second inclined pattern portion 120s2 can be disposed at different angles (or multiple angles) with respect to the upper surface 110a of the substrate 110 to reflect light directed to adjacent sub-pixels toward the emitting sub-pixel. In other words, the display apparatus 100 according to one embodiment of the present disclosure can be provided with multiple surfaces (or multiple inclined surfaces) in which the reflective portions 130 have different angles.

On the other hand, when the first angle θ₁ is larger than the second angle θ₂, light is more likely not to be directed onto the reflective portion 130 (or a second inclined reflective portion 133) on the second inclined pattern portion 120s2 by the waveguide, but to be reflected from the reflective portion 130 (or the first inclined reflective portion 131) disposed on the first inclined pattern portion 120s1 and extracted to the outside of the substrate 110.

For a general display apparatus having a single side with a reflective portion disposed to be spaced apart position from the pixel electrode, when the angle formed between the upper surface of the substrate and the reflective portion (or the inclined plane of the overcoat layer adjacent to the pixel electrode) is large, the light directed to the adjacent sub-pixel by the wave guide can be reflected by the reflective portion, thereby having the advantage of high light extraction efficiency. However, there is a disadvantage that the light totally reflected from the interface (or boundary) between the substrate and the outside air is reflected by the reflective portion, then is not directly extracted to the outside of the substrate, but is totally reflected from the inside of the substrate through being reflected from the cathode (or counter electrode), and there is a high probability that it cannot be extracted to the outside.

Furthermore, for a general display apparatus having a single side with a reflective portion 130 disposed to be spaced apart from the pixel electrode 114, if the angle formed between the upper surface 110a of the substrate 110 and the reflective portion 130 (or the inclined plane of the overcoat layer 113 adjacent to the pixel electrode 114) is small, the light totally reflected from the interface (or boundary) between the substrate 110 and the outside air can be directly extracted to the outside of the substrate after being reflected by the reflective portion 130, which has the advantage of high light extraction efficiency. However, there is a disadvantage that light directed to an adjacent sub-pixel by the wave guide is likely to be totally reflected between the reflective portion 130 and the overcoat layer 113 and not be extracted to the outside. In other words, the wave-guided light cannot escape the critical angle (or the wave-guided light can have an angle greater than the critical angle) and can be guided along the inclined surface of the reflective portion 130 and/or the overcoat layer 113 and may not be extracted to the outside.

Thus, the display apparatus 100 includes inclined surfaces of the pattern portion 120 (or first and second inclined pattern portions 120s1, 120s2) at multiple angles (first angle θ₁ and second angle θ₂) with respect to the upper surface 110a of the substrate 110, thus both the light that is extinguished by the wave guide and the light that is totally reflected and extinguished inside the substrate 110 can be output to the outside in the form of the first reflected light EL1 and the second reflected light EL2, the light extraction efficiency can be maximized.

As a result, light that is extinguished by the wave guide can be directed to the outside of the substrate 110 by the first overcoat layer having a first thickness D1 and the first inclined pattern portion 120s1 (or the first inclined reflective portion 131) having the first angle θ1. Also, the light that is trapped within the substrate 110 and is extinguished can be directed to the outside of the substrate 110 by the second overcoat layer provided with the second thickness D2 and the second inclined pattern portion 120s2 (or the second inclined reflective portion 133) provided with the second angle θ₂. Alternatively, light that is trapped within the substrate 110 and extinguished can be directed to the outside of the substrate 110, due to a thickness DT of the overcoat layer 113, and the second inclined pattern portion 120s2 (or the second inclined reflective portion 133). Here, the thickness DT is a thickness of the overcoat layer 113 including the first inclined pattern portion 120s1 and the second inclined pattern portion 120s2, and the second inclined pattern portion 120s2 is provided at the second angle θ₂.

On the other hand, the pattern portion 120 can be provided to surround the remainder of the light emission area EA except for one side of the light emission area EA where the circuit area CA is provided. For example, as shown in FIG. 2, the pattern portion 120 may not be disposed only on one side of the light emission area EA adjacent to the circuit area CA but may be disposed only on the remainder of the light emission area EA. This is because the pixel electrode 114 disposed in the light emission area EA needs to be connected to the circuit area CA, thus the pattern portion 120 is not able to be formed between the light emission area EA and the circuit area CA. Accordingly, the pattern portion 120 can be disposed only in the area where the pattern portion 120 is formed. Therefore, as shown in FIG. 2, the display apparatus 100 can have a structural feature in which the pattern portion 120 is disposed to surround the remainder of the light emission area EA except for one side of the light emission area EA where the circuit area CA is provided.

Referring to FIG. 2, the pattern portion 120 can include a first pattern line 121 disposed long in the first direction (X-axis direction) between the circuit area CA and the light emission area EA and a second pattern line 122 disposed long in the second direction (Y-axis direction) crossing the first direction (X-axis direction). As shown in FIG. 2, the first pattern line 121 can correspond to the pattern portion 120 disposed in a horizontal direction, and the second pattern line 122 can correspond to the pattern portion 120 disposed in a vertical direction.

In addition, the first pattern line 121 can include a bottom surface 121b and an inclined surface 121s and the second pattern line 122 can include a bottom surface 122b and an inclined surface 122s. Because each of the bottom surface 121b and the inclined surface 121s of the first pattern line 121 and each of the bottom surface 122b and the inclined surface 122s of the second pattern line 122 are the same as each of the bottom surface 120b and the inclined surface 120s of the pattern portion 120, their description is omitted. The first pattern line 121 and the second pattern line 122 can also be connected to one in the non-light emission area NEA (or the peripheral area) to surround the light emission area EA.

Further, the first pattern line 121 can be disposed between the subpixels SP for emitting light of the same color. For example, the first pattern line 121 can be disposed between the first subpixels SP1 disposed in the second direction (Y-axis direction). Therefore, the first pattern line 121 can be disposed long in the first direction (X-axis direction). In contrast, the second pattern line 122 can be disposed between the subpixels SP for emitting light of different colors. For example, the second pattern line 122 can be disposed between the third subpixel SP3 that is a blue subpixel, and the fourth subpixel SP4 that is a green pixel. Therefore, the second pattern line 122 can be disposed long in the second direction (Y-axis direction).

Because the second pattern line 122 is disposed between the subpixels SP for emitting light of different colors, the reflective portion 130 on the second pattern line 122 can prevent light of different colors from being emitted to other adjacent subpixels SP. Therefore, the display apparatus 100 according to the present disclosure can prevent color mixture (or color distortion) between the subpixels SP for emitting light of different colors, thereby improving color purity.

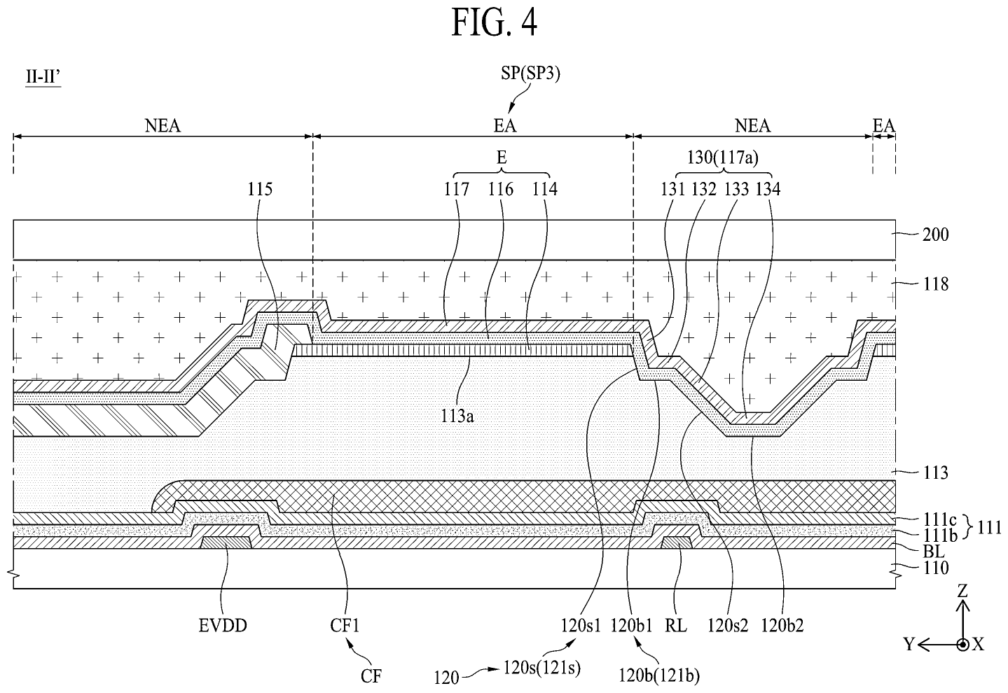

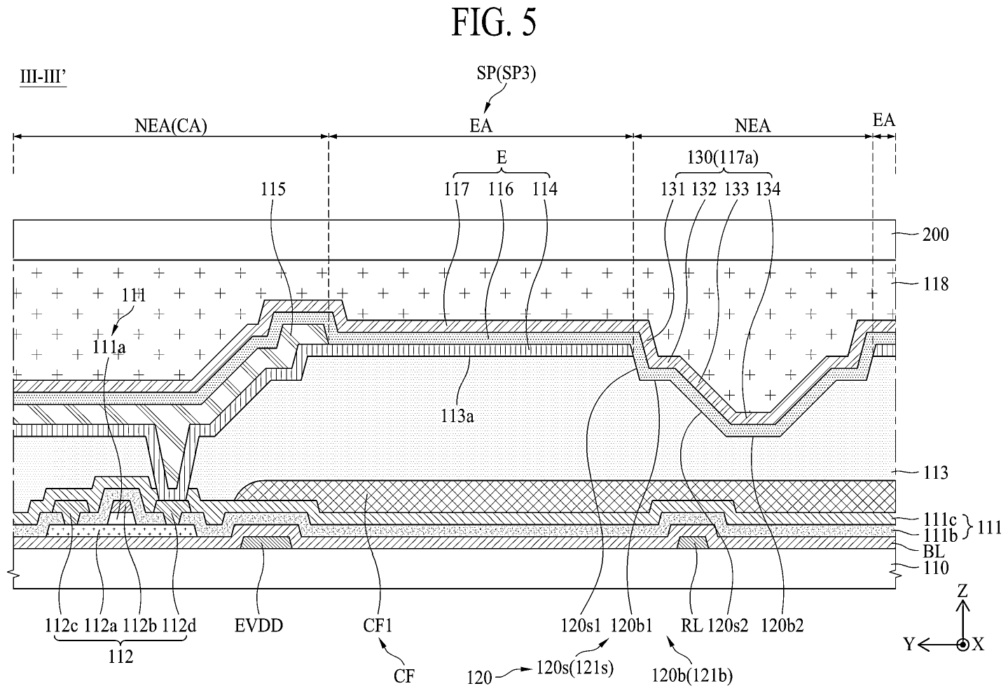

Next, FIG. 4 is a schematic cross-sectional view of the line II-II′ shown in FIG. 2, and FIG. 5 is a schematic cross-sectional view of the line III-III′ shown in FIG. 2. Referring to FIGS. 4 and 5, in the non-light emission area NEA where the circuit area CA is disposed, the bank 115 can be disposed to cover the circuit area CA (or the thin film transistor 112, shown in FIG. 5). Also, each of the pixel power line EVDD and the reference line RL can be disposed so as not to overlap the light emission area EA in the third direction (Z-axis direction). Accordingly, the display apparatus 100 can enable light emitted from the light emission area EA to be directed to the outside of the substrate 110 without interference from the pixel power lines EVDD and the reference line RL, so that a decrease in light emission efficiency can be prevented.

Hereinafter, referring to FIG. 5, a structure of each of the plurality of subpixels SP will be described in detail. Referring to FIG. 5, the display apparatus 100 according to one embodiment of the present disclosure can further include a buffer layer BL, a circuit element layer 111, a thin film transistor 112, an overcoat layer 113, a pixel electrode 114, a bank 115, an organic light emitting layer 116, a reflective electrode 117, an encapsulation layer 118 and a color filter CF.

In more detail, each of the subpixels SP according to one embodiment can include a circuit element layer 111 provided on an upper surface of a buffer layer BL, including a gate insulating layer 111a, an interlayer insulating layer 111b and a passivation layer 111c, an overcoat layer 113 provided on the circuit element layer 111, a pixel electrode 114 provided on the overcoat layer 113, a bank 115 covering an edge of the pixel electrode 114, an organic light emitting layer 116 on the pixel electrode 114 and the bank 115, a reflective electrode 117 on the organic light emitting layer 116, and an encapsulation layer 118 on the reflective electrode 117.

In addition, the thin film transistor 112 for driving the subpixel SP can be disposed on the circuit element layer 111. Also, the circuit element layer 111 can be expressed as the term of an inorganic film layer. Further, the buffer layer BL can be included in the circuit element layer 111 together with the gate insulating layer 111a, the interlayer insulating layer 111b and the passivation layer 111c. The pixel electrode 114, the organic light emitting layer 116 and the reflective electrode 117 can also be included in the light emitting element layer E.

In addition, the buffer layer BL can be formed between the substrate 110 and the gate insulating layer 111a to protect the thin film transistor 112. The buffer layer BL can also be disposed on the entire surface (or front surface) of the substrate 110. Further, the pixel power line EVDD for pixel driving can be disposed between the buffer layer BL and the substrate 110. The pixel power line EVDD can also be disposed below the bank 115 while being spaced apart from the thin film transistor 112. Further, the reference line RL can also be disposed between the buffer layer BL and the substrate 110. The reference line RL can also be disposed in the non-light emission area NEA that does not overlap with the light emission area EA. In addition, the buffer layer BL can serve to block diffusion of a material contained in the substrate 110 into a transistor layer during a high temperature process of a manufacturing process of the thin film transistor. Optionally, the buffer layer BL can be omitted in some cases.

Also, the thin film transistor 112 (or a drive transistor) according to an example can include an active layer 112a, a gate electrode 112b, a source electrode 112c, and a drain electrode 112d. In particular, the active layer 112a can include a channel area, a drain area and a source area, which are formed in a thin film transistor area of a circuit area of the subpixel SP. The drain area and the source area can be spaced apart from each other with the channel area interposed therebetween.

Further, the active layer 112a can be formed of a semiconductor material based on any one of amorphous silicon, polycrystalline silicon, oxide and organic material. Also, the gate insulating layer 111a can be formed on the channel area of the active layer 112a. As an example, the gate insulating layer 111a can be formed in an island shape only on the channel area of the active layer 112a, or can be formed on an entire front surface of the substrate 110 or the buffer layer BL, which includes the active layer 112a.

In addition, the gate electrode 112b can be formed on the gate insulating layer 111a to overlap the channel area of the active layer 112a. Further, the interlayer insulating layer 111b can be formed on the gate electrode 112b and the drain area and the source area of the active layer 112a. As shown in FIG. 5, the interlayer insulating layer 111b can be formed in the circuit area and an entire light emission area, in which light is emitted to the subpixel SP. However, embodiments of the present disclosure are not limited thereto, and the interlayer insulating layer 111b can be patterned between the drain electrode 112d and the gate electrode 112b and drain region of the active layer 112a and can be arranged in an island shape, and moreover, can be patterned between the source electrode 112c and the gate electrode 112b and source region of the active layer 112a and can be arranged in an island shape.

In addition, the source electrode 112c can be electrically connected to the source area of the active layer 112a through a source contact hole provided in the interlayer insulating layer 111b overlapped with the source area of the active layer 112a. Further, the drain electrode 112d can be electrically connected to the drain area of the active layer 112a through a drain contact hole provided in the interlayer insulating layer 111b overlapped with the drain area of the active layer 112a.

Also, the drain electrode 112d and the source electrode 112c can be made of the same metal material. For example, each of the drain electrode 112d and the source electrode 112c can be made of a single metal layer, a single layer of an alloy or a multi-layer of two or more layers, which is the same as or different from that of the gate electrode.

In addition, the circuit area can further include first and second switching thin film transistors disposed together with the thin film transistor 112, and a capacitor. Because each of the first and second switching thin film transistors is provided on the circuit area of the subpixel SP to have the same structure as that of the thin film transistor 112, its description will be omitted. The capacitor can be provided in an overlap area between the gate electrode 112b and the source electrode 112c of the thin film transistor 112, which overlap each other with the interlayer insulating layer 111b interposed therebetween.

Additionally, to prevent a threshold voltage of the thin film transistor provided in a pixel area from being shifted by light, the display panel or the substrate 110 can further include a light shielding layer provided below the active layer 112a of at least one of the thin film transistor 112, the first switching thin film transistor or the second switching thin film transistor. In addition, the light shielding layer can be disposed between the substrate 110 and the active layer 112a to shield light incident on the active layer 112a through the substrate 110, thereby minimizing a change in the threshold voltage of the transistor due to external light. Also, because the light shielding layer is provided between the substrate 110 and the active layer 112a, the thin film transistor can be prevented from being seen by a user.

In addition, the passivation layer 111c can be provided on the substrate 110 to cover the pixel area. As shown, the passivation layer 111c covers a drain electrode 112d, a source electrode 112c and a gate electrode 112b of the thin film transistor 112, and the buffer layer BL.

On the other hand, the display apparatus 100 can be provided that the bank 115 is disposed only on one side of the light emission area EA in which the circuit area CA is disposed. Accordingly, as shown in FIG. 5, the pixel power line EVDD can be disposed to overlap the bank 115 in the third direction (Z-axis direction), and the reference line RL may not overlap the bank 115 in the third direction (Z-axis direction). Further, the passivation layer 111c can be formed over the circuit area and the light emission area. The passivation layer 111c can also be omitted, and the color filter CF can be disposed on the passivation layer 111c.

In addition, the overcoat layer 113 can be provided on the substrate 110 to cover the passivation layer 111c and the color filter CF. When the passivation layer 111c is omitted, the overcoat layer 113 can be provided on the substrate 110 to cover the circuit area. The overcoat layer 113 can also be formed in the circuit area CA in which the thin film transistor 112 is disposed and the light emission area EA. In addition, the overcoat layer 113 can be formed in the other non-display area NDA except a pad area PA of the non-display area NDA and the entire display area DA. For example, the overcoat layer 113 can include an extension portion (or an enlarged portion) extended or enlarged from the display area DA to the other non-display area NDA except the pad area PA. Therefore, the overcoat layer 113 can have a size relatively wider than that of the display area DA.

In addition, the overcoat layer 113 according to one example can be formed to have a relatively thick thickness, thereby providing a flat surface on the display area DA and the non-display area NDA. For example, the overcoat layer 113 can be made of an organic material such as photo acryl, benzocyclobutene, polyimide and fluorine resin.

By being provided with an upper surface 113a of the overcoat layer 113 to be flat, the pixel electrodes 114 on the overcoat layer 113 can also be provided to be flat, and the organic light emitting layer 116 and reflective electrodes 117 formed thereon can also be provided to be flat. Because the pixel electrode 114, the organic light emitting layer 116, the reflective electrode 117, that is, the light emitting element layer E is provided to be flat in the light emission area EA, a thickness of each of the pixel electrode 114, the organic light emitting layer 116 and the reflective electrode 117 in the light emission area EA can be uniformly formed. Therefore, the organic light emitting layer 116 can be uniformly emitted without deviation in the light emission area EA.

On the other hand, the pattern portion 120 can be formed by patterning and removing a portion of the overcoat layer 113. In particular, the pattern portion 120, according to one example, can be formed on the overcoat layer 113 by a photo process utilizing a mask having an opening, and by a patterning (or etching) or ashing process after the photo process. As described above, the pattern portion 120 can include a first pattern line 121 and a second pattern line 122, and the first pattern line 121 and the second pattern line 122 can be disposed to surround the remainder of the light emission area EA except for one side of the light emission area EA to which the circuit area CA is adjacent. After the pattern portion 120 is formed, the pixel electrodes 114 on the overcoat layer 113 can be formed in a pattern for each sub-pixel SP, and then the organic light emitting layer 116 and the reflective electrodes 117 can be formed on the entire surface.

Referring again to FIG. 5, the color filter CF disposed in the light emission area EA can be provided between the substrate 110 (or passivation layer 111c) and the overcoat layer 113. Accordingly, the color filter CF can be disposed between the reference line RL and the reflective portion 130 or between the reference line RL and the pattern portion 120. Further, the color filter CF can include a red color filter (or a third color filter) (not shown) that converts white light emitted by the organic light emitting layer 116 into red light, a blue color filter (or a first color filter) (CF1) (shown in FIG. 3) that converts white light into blue light, and a green color filter (or a second color filter) (CF2) that converts white light into green light. The second sub-pixel SP2, which is a white sub-pixel, can also not include a color filter because the organic light emitting layer 116 emits white light.

As shown in FIG. 3, color filters (e.g., the first color filter (CF1) and the second color filter (CF2)) having different colors partially overlap each other at a boundary portion of the plurality of subpixels SP. In this instance, the display apparatus 100 can prevent the light emitted from each subpixel SP from being emitted to the adjacent subpixel SP due to the color filters overlapped with each other at the boundary portion of the subpixels SP, thereby preventing color mixture between the subpixels SP from occurring.

Referring again back to FIG. 5, the pixel electrode 114 of the subpixel SP can be formed on the overcoat layer 113. Further, the pixel electrode 114 can be connected to a drain electrode or a source electrode of the thin film transistor 112 through a contact hole passing through the overcoat layer 113 and the passivation layer 111c. The one edge portion of the pixel electrode 114 can also be covered by the bank 115, and the pixel electrode 114 can be made of at least one of a transparent metal material or a semi-transmissive metal material.

Because the display apparatus 100 according to an embodiment of the present disclosure is configured as the bottom emission type, the pixel electrode 114 can be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag. Meanwhile, the material constituting the pixel electrode 114 can include MoTi. The pixel electrode 114 can also be a first electrode or an anode electrode.

In addition, the bank 115 can be an area, which does not emit light, and disposed on one side of the light emission area EA of each of the plurality of sub-pixels SP. For example, the bank 115 can be disposed in the non-light emission area NEA where the circuit area CA is disposed. As shown in FIG. 5, the bank 115 can be formed to cover a portion where one edge of the pixel electrode 114 in each of the sub-pixels SP is connected to the thin film transistor 112. That is, the bank 115 can partially cover the pixel electrode 114. Accordingly, the bank 115 can prevent the pixel electrode 114 and reflective electrode 117 from contacting in the circuit area CA. Further, the exposed portion of the pixel electrode 114 that is not covered by the bank 115 can be included in the light emitting portion (or light emission area EA).

As described above, the bank 115 is disposed in the non-light emission area NEA in which the circuit area CA is disposed, so that the non-light emission area NEA on the left and the non-light emission area NEA on the right can be asymmetrically provided with respect to the light emission area EA of FIG. 5. For example, based on the light emission area EA of FIG. 5, the left non-light emission area NEA can be provided as a structure including the thin film transistor 112 and the bank 115, and the right non-light emission area NEA can be provided as a structure without the bank 115 on the pattern portion 120.

After the bank 115 is formed, an organic light emitting layer 116 can be formed to cover the pixel electrodes 114 and the bank 115. Thus, the bank 115 can be provided between the pixel electrodes 114 and the organic light emitting layer 116. The bank 115 can also be expressed in terms of a pixel-defining membrane. Further, the bank 115 according to one example can comprise organic material and/or inorganic material and can be concave or inclined along the profile of the pattern portion 120.

Referring again back to FIG. 5, the organic light emitting layer 116 can be formed on the pixel electrodes 114 and the bank 115. According to one example, the organic light emitting layer 116 can be disposed in the light emission area EA and the non-light emission area NEA. Further, the organic light emitting layer 116 can be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the organic light emitting layer 116 can emit light. The organic light emitting layer 116 can also be formed of a plurality of subpixels SP and a common layer provided on the bank 115.

In addition the organic light emitting layer 116 according to an embodiment can be provided to emit white light. The organic light emitting layer 116 can also include a plurality of stacks which emit light of different colors. For example, the organic light emitting layer 116 can include a first stack, a second stack, and a charge generating layer (CGL) provided between the first stack and the second stack. The light emitting layer can also be provided to emit the white light, and thus, each of the plurality of subpixels SP can include a color filter CF suitable for a corresponding color.

In addition, the first stack can be provided on the pixel electrode 114 and can be implemented a structure where a hole injection layer (HIL), a hole transport layer (HTL), a blue emission layer (EML(B)), and an electron transport layer (ETL) are sequentially stacked.

Further, the charge generating layer can supply an electric charge to the first stack and the second stack. In particular, the charge generating layer can include an N-type charge generating layer for supplying an electron to the first stack and a P-type charge generating layer for supplying a hole to the second stack. The N-type charge generating layer can also include a metal material as a dopant. In addition, the second stack can be provided on the first stack and can be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack can be arranged all over the plurality of subpixels SP. The organic light emitting layer 116, according to another example, can be provided in a three-stacked structure or a four-stacked structure, depending on the number of stacks stacked.

In addition, the reflective electrode 117 can be formed on the organic light emitting layer 116 and can be disposed in the light emission area EA and the non-light emission area NEA. The reflective electrode 117 according to one example can also include a metal material and can reflect the light emitted from the organic light emitting layer 116 in the plurality of subpixels SP toward the lower surface of the substrate 110. Therefore, the display apparatus 100 according to one embodiment of the present disclosure can be implemented as a bottom emission type display apparatus.

Further, the display apparatus 100 according to one embodiment of the present disclosure is a bottom emission type and has to reflect light emitted from the light emitting layer 116 toward the substrate 110, and thus the reflective electrode 117 can be made of a metal material having a high reflectance. For example, the reflective electrode 117 according to one example can be formed of a metal material having high reflectance such as a stacked structure (Ti/Al/Ti) of aluminum and titanium, a stacked structure (ITO/AI/ITO) of aluminum and ITO, an Ag alloy and a stacked structure (ITO/Ag alloy/ITO) of Ag alloy and ITO. The Ag alloy can be an alloy such as silver (Ag), palladium (Pd) and copper (Cu). The reflective electrode 117 can be expressed as terms such as a second electrode, a cathode electrode and a counter electrode.

On the other hand, in the display apparatus 100 according to one embodiment of the present disclosure, the reflective portion 130 can be a part of the reflective electrode 117. Thus, the reflective portion 130 can reflect light, which is directed toward the adjacent sub-pixel SP, toward the light emission area EA of the emitting sub-pixel SP. The reflective portion 130 is a portion of the reflective electrode 117, and can be denoted by the drawing symbol 117a, as shown in FIG. 3. Further, the reflective portion 130 can refer to a reflective electrode 117 that overlaps the pattern portion 120. In one example, the reflective portion 130 can include a reflective electrode 117a that is inclined while overlaps the pattern portion 120 and a reflective electrode 117a that is flat while overlaps the pattern portion 120.

In addition, the inclined reflective electrode 117a can include the first inclined reflective portion 131 and the second inclined reflective portion 133. Further, the flat reflective electrode 117a can include a first flat reflective portion 132 and a second flat reflective portion 134. As a result, the reflective portion 130 disposed on the pattern portion 120 can include the first inclined reflective portion 131, the first flat reflective portion 132, the second inclined reflective portion 133, and the second flat reflective portion 134.

In addition, the first inclined reflective portion 131 according to one example can be disposed on the first inclined pattern portion 120s1. The entire first inclined reflective portion 131 can also be disposed on the first inclined pattern portion 120s1, but is not limited thereto, and a portion of the first inclined reflective portion 131 can be disposed on the first inclined pattern portion 120s1 and the other portion can be disposed on the first flat pattern portion 120b1. This is because the first inclined reflective portion 131 is shifted with respect to the first inclined pattern portion 120s1 by a thickness of the organic light emitting layer 116. Further, the first inclined pattern portion 120s1 can be provided with a horizontal length L₁ from a point where the first flat pattern portion 120b1 and the first inclined pattern portion 120s1 contact to an end of the light emission area EA. The horizontal length L₁ of the first inclined pattern portion 120s1 can also be derived by the first thickness D1 of the first overcoat layer and the first angle θ₁.

In addition, the first flat reflective portion 132, according to one example, is connected to the first inclined reflective portion 131 and can be disposed on the first flat pattern portion 120b1. Also, the entire first flat reflective portion 132 can be disposed on the first flat pattern portion 120b1, but is not limited thereto, and a portion of the first flat reflective portion 132 can be disposed on the first flat pattern portion 120b1 and the other portion of the first flat reflective portion 132 can be disposed on the second inclined pattern portion 120s2. This is because the first flat reflective portion 132 is shifted with respect to the first flat pattern portion 120b1 by a thickness of the organic light emitting layer 116. Further, the first flat pattern portion 120b1 can have a horizontal length L_{F} from a point where the first flat pattern portion 120b1 and the first inclined pattern portion 120s1 contact to a point where the first flat pattern portion 120b1 and the second inclined pattern portion 120s2 contact.

In addition, the second inclined reflective portion 133, according to one example, is connected to the first flat reflective portion 132 and can be disposed on the second inclined pattern portion 120s2. Also, the entire second inclined reflective portion 133 can be disposed on the second inclined pattern portion 120s2, but is not limited thereto, and a portion of the second inclined reflective portion 133 can be disposed on the second inclined pattern portion 120s2 and the other portion of the second inclined reflective portion 133 can be disposed on the second flat pattern portion 120b2. This is because the second inclined reflective portion 133 is shifted with respect to the second inclined pattern portion 120s2 by a thickness of the organic light emitting layer 116. Further, the second inclined pattern portion 120s2 can be provided with a horizontal length L₂ from a point where the first flat pattern portion 120b1 and the second inclined pattern portion 120s2 contact to a point where the second flat pattern portion 120b2 and the second inclined pattern portion 120s2 contact. The horizontal length L₂ of the second inclined pattern portion 120s2 can also be derived by the second thickness D2 of the second overcoat layer and the second angle θ₂.

Here, the overall horizontal length from the point where the second flat pattern portion 120b2 and the second inclined pattern portion 120s2 contact to the end of the light emission area EA can be L_{T}. The overall horizontal length L_{T} can also be the sum of the horizontal length L₁ of the first inclined pattern portion 120s1 and the horizontal length L_{F} of the first flat pattern portion 120b1 and the horizontal length L₂ of the second inclined pattern portion 120s2.

Further, the second flat reflective portion 134, according to one example, is connected to the second inclined reflective portion 133 and can be disposed on the second flat pattern portion 120b2. The entire second flat reflective portion 134 can also be disposed on the second flat pattern portion 120b2. This is because the second flat reflective portion 134 is formed with a narrower width than the second flat pattern portion 120b2 by the thickness of the organic light emitting layer 116.

Thus, the display apparatus 100 according to one embodiment of the present disclosure includes the first inclined reflective portion 131 disposed at the first angle θ₁ with respect to the first extension line EXL1, and the second inclined reflective portion 133 disposed at the second angle θ₂ with respect to the second extension line EXL2, and the first inclined reflective portion 131 and the second inclined reflective portion 133 can reflect light directed toward an adjacent sub-pixel SP and/or light that is extinguished by being total reflected from the interfaces, to a light emission area EA and/or the non-light emission area NEA of the emitting sub-pixel SP.

In addition, the encapsulation layer 118 is formed on the reflective electrode 117 and serves to prevent oxygen or moisture from being permeated into the organic light emitting layer 116 and the reflective electrode 117. To this end, the encapsulation layer 118 can include at least one inorganic film and at least one organic film.

Meanwhile, as shown in FIG. 3, the encapsulation layer 118 can be disposed not only in the light emission area EA but also in the non-light emission area NEA. The encapsulation layer 118 can also be disposed between the reflective electrode 117 and an opposing substrate 200.

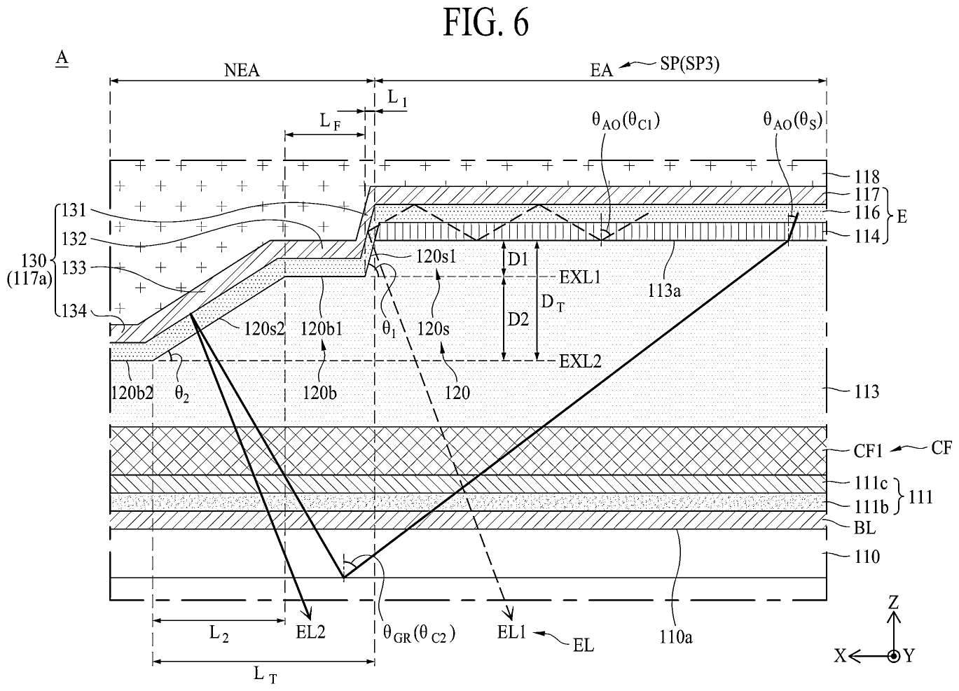

Hereinafter, with reference to FIG. 6, the first angle θ₁ and the second angle θ₂ at which the first inclined pattern portion 120s1 (or first inclined reflective portion 131) and the second inclined pattern portion 120s2 (or the second inclined reflective portion 133), respectively, of the display apparatus 100 according to one embodiment of the present disclosure are disposed will be described in detail by associating mathematical expressions. In particular, FIG. 6 is a schematic enlarged cross-sectional view of portion A shown in FIG. 3.

Referring to FIG. 6, the first angle θ₁ and the second angle θ₂ can be optimized angles by mathematical expressions regarding the critical angle (or total reflection angle) between the pixel electrode 114 and the overcoat layer 113, the refractive index of the pixel electrode 114, the refractive index of the overcoat layer 113, and the refractive index of the outside air. In addition, the θ_{AO} shown in FIG. 6 can be an incidence angle at which light emitted by the organic light emitting layer 116 is incident on the interface between the pixel electrode 114 and the overcoat layer 113. θ_{GR} can be an incidence angle at which light emitted by the organic light emitting layer 116 is incident into an interface between the substrate 110 and the outside air adjacent to the substrate 110. θ_{C2} can be an angle at which light emitted by the organic light emitting layer 116 is totally reflected at the interface between the substrate 110, and the outside air adjacent to the substrate 110. That is, θ_{C2} can be a critical angle at the interface between the substrate 110 and the outside air.

In one example, the first angle θ₁ can be provided to satisfy a mathematical expression below (Equation 1),

$${θ}_{1} > 90 ° - {θ}_{c 1}$$

θ_{C1} can denote an angle at which a portion of the light emitted by the organic light emitting layer 116 is totally reflected between the pixel electrode 114 and the overcoat layer 113. That is, θ_{C1} can denote a critical angle between the pixel electrode 114 and the overcoat layer 113. For example, θ_{C1} can be less than 90°. On the other hand, in Equation 1 above, the angle θ_{C1} at which a portion of the light emitted by the organic light emitting layer 116 is totally reflected between the pixel electrode 114 and the overcoat layer 113 can be provided to satisfy the mathematical expression below (or Equation 2),

$${θ}_{c 1} = arcsin ( \frac{{n}_{oc}}{{n}_{Andoe}} )$$

n_{oc} can denote a refractive index of the overcoat layer 113, and n_{Anode} can denote a refractive index of the pixel electrode 114. On the other hand, when the refractive index of the pixel electrode 114 is greater than the refractive index of the overcoat layer 113, light having an angle of emission greater than θ_{C1} (e.g., greater than) 90° can be extinguished inside the substrate by the wave guide. Here, the light emission angle can refer to an angle at which light emitted by the organic light emitting layer 116 is incident on the interface between the overcoat layer 113 and the pixel electrode 114. Thus, θ_{C1} can be provided to be less than 90°. According to Equation 1 above, if θ_{C1} is greater than 90°, the first angle θ₁ has a zero or negative value, so that the first inclined pattern portion 120s1 cannot be formed. Therefore, the display apparatus 100 according to one embodiment of the present disclosure is provided such that when the refractive index of the pixel electrode 114 is greater than the refractive index of the overcoat layer 113, light emitted from the organic light emitting layer 116 is incident to the interface between the overcoat layer 113 and the pixel electrode 114 at an angle equal to or less than θ_{C1} (or less than) 90°, then the light can be reflected from the first inclined reflective portion 131 formed at the first angle θ₁ satisfying Equations 1 and 2 above and be directing to the outside of the substrate 110.

On the other hand, when a portion of the light emitted by the organic light emitting layer 116 is not directed to the outside of the substrate but trapped inside the substrate 110, the angle θₛ of a portion of the light incident on the interface between the pixel electrode 114 and the overcoat layer 113 is provided to satisfy the mathematical expression (or Equation 3) as shown below,

$$270 ° - 2 {θ}_{1} - {θ}_{c 1} > {θ}_{S}$$

θ₁ can denote the first angle, and θ_{C1} can be an angle at which a portion of the light emitted by the organic light emitting layer 116 is totally reflected between the pixel electrode 114 and the overcoat layer 113.

In the display apparatus 100 according to one embodiment of the present disclosure, the first angle θ₁ can be provided to satisfy a mathematical expression below (or Equation 4),

$${θ}_{1} < 135 ° - 0.5 arcsin ( \frac{{n}_{oc}}{{n}_{Andoe}} ) - 0.5 arcsin ( \frac{{n}_{oc}}{{n}_{Andoe}} sin ( arcsin ( \frac{1}{{n}_{oc}} ) ) )$$

n_{oc} can be a refractive index of the overcoat layer 113, and n_{Anode} can be a refractive index of the pixel electrode 114. Thus, in the display apparatus 100 according to one embodiment of the present disclosure, the first angle θ₁ can be provided to satisfy the above equations 1 and 4, which can be represented by a following mathematical expression (or Equation 5).

$$90 ° - {θ}_{c 1} < {θ}_{1} < 135 ° - 0.5 arcsin ( \frac{{n}_{oc}}{{n}_{Andoe}} ) - 0.5 arcsin ( \frac{{n}_{oc}}{{n}_{Andoe}} sin ( arcsin ( \frac{1}{{n}_{oc}} ) ) )$$

In the display apparatus 100 according to one embodiment of the present disclosure, the second angle θ₂ can be provided to satisfy a mathematical expression (or Equation 6) such as the following,

$${θ}_{2} < arcsin ( \frac{{n}_{air}}{{n}_{oc}} )$$

n_{oc} can denote a refractive index of the overcoat layer 113, and nₐᵢᵣ can denote a refractive index of the outside air adjacent to the substrate 110 (or a lower surface of the substrate 110).

As a result, in the display apparatus 100 according to one embodiment of the present disclosure, the refractive index of the pixel electrode 114, the refractive index of the overcoat layer 113, the critical angle (or total reflection angle) between the pixel electrode 114 and the overcoat layer 113, and the refractive index of the outside air can be provided to satisfy Equation 1 to Equation 6, as shown in FIG. 6, thus light directed toward the adjacent sub-pixel (or light that is extinguished by the wave guide and light that is totally reflected and extinguished inside the substrate) can be reflected from the reflective portion 130 and directed to the light emission area EA or the non-light emission area NEA of the sub-pixel in the form of a first reflected light EL1 or a second reflected light EL2, thereby improving the light extraction efficiency.

Furthermore, in the display apparatus 100 according to one embodiment of the present disclosure, the first angle θ₁ at which the first inclined pattern portion 120s1 (or the first inclined reflective portion 131) is disposed, and the second angle θ₂ at which the second inclined pattern portion 120s2 (or the second inclined reflective portion 133) is disposed, can be provided to be optimal angles according to the above equations 1 to 6, thereby maximizing the reflection efficiency of the reflective portion 130. For example, the light extraction efficiency of the first reflected light EL1 by the first inclined reflective portion 131 and the light extraction efficiency of the second reflected light EL2 by the second inclined reflective portion 133 can be maximized, thereby maximizing the light extraction efficiency.

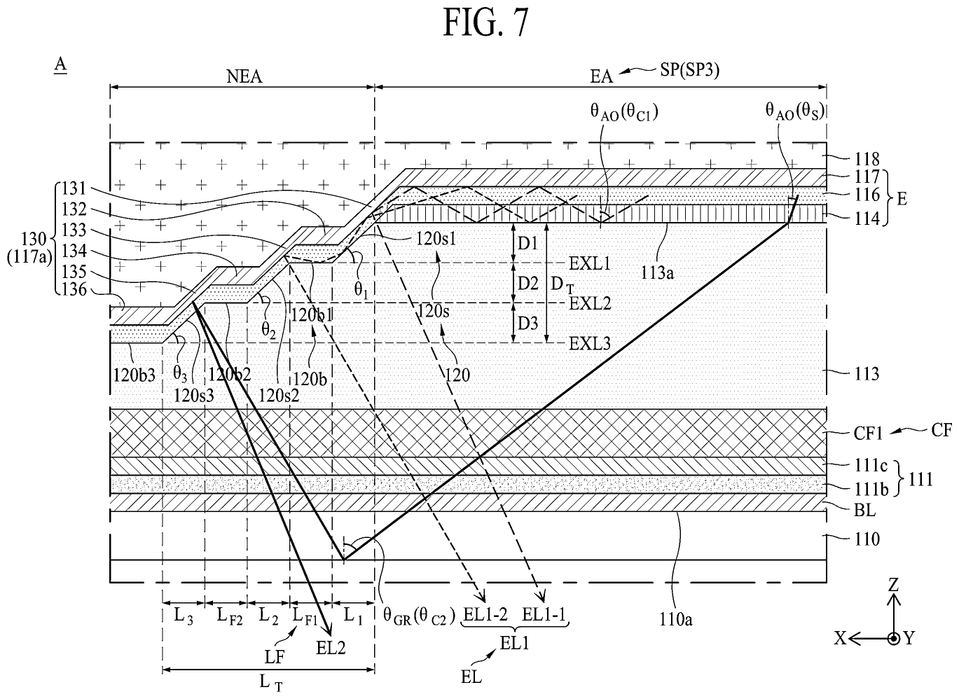

Next, FIG. 7 is a schematic enlarged cross-sectional view illustrating a display apparatus according to another embodiment of the present disclosure, as another example of the portion A shown in FIG. 3. Referring to FIG. 7, the display apparatus 100 is similar to the display apparatus according to FIG. 1 described above, except that the structure of the pattern portion 120 and the reflective portion 130 has been changed. Therefore, the same drawing symbols have been assigned to the same configuration, and only the different configurations will be described hereinafter.

For the display apparatus according to FIG. 1, the inclined surface 120s of the pattern portion 120 is provided to include the first inclined pattern portion 120s1 disposed at the first angle θ₁ with respect to the upper surface 110a of the substrate 110 and the second inclined pattern portion 120s2 disposed at the second angle θ₂, and thus the reflective portion 130 can include the first inclined reflective portion 131 disposed at the first angle θ₁ and the second inclined reflective portion 133 disposed at the second angle θ₂. Accordingly, for the display apparatus according to FIG. 1, the first inclined reflective portion 131 and the second inclined reflective portion 133 provided at multiple angles (or the same angle), i.e., the inclined reflective portion provided in two stages, enable the light that is extinguished by the wave guide and the light that is totally reflected and extinguished inside the substrate, to be output to the outside in the form of the first reflected light EL1 and the second reflected light EL2, thereby improving light extraction efficiency.

In contrast, for the display apparatus according to FIG. 7, the pattern portion 120 can further include a third inclined pattern portion 120s3 and a third flat pattern portion 120b3. In addition, the third inclined pattern portion 120s3 according to an example can be disposed between the second inclined pattern portion 120s2 and the substrate 110 and can be disposed at a third angle θ₃ with respect to the upper surface 110a of the substrate 110. Here, the third angle θ₃ can be equal to or different from the second angle θ₂. As shown in FIG. 7, a third extension line EXL3 is disposed parallel to the upper surface 110a of the substrate 110, so the third inclined pattern portion 120s3 can be represented as being disposed at the third angle θ₃ with respect to the third extension line EXL3. The third extension line EXL3 can refer to an imaginary line extending in the first direction (X-axis direction) from a point where the third inclined pattern portion 120s3 and the third flat pattern portion 120b3 contact. The third flat pattern portion 120b3 according to an example can be disposed spaced apart from the second flat pattern portion 120b2 and can be connected to the third inclined pattern portion 120s3. Accordingly, as shown in FIG. 7, the display apparatus 100 according to another embodiment of the present disclosure can be provided with the inclined pattern portions 120s in three stages.

On the other hand, because the display apparatus 100 according to another embodiment of the present disclosure includes the pattern portion 120 in three stages, the reflective portion 130 disposed on the pattern portion 120 can also be provided in three stages. In addition, the reflective portion 130 according to one example can include the first inclined reflective portion 131, the first flat reflective portion 132, the second inclined reflective portion 133, the second flat reflective portion 134, the third inclined reflective portion 135, and the third flat reflective portion 136. Also, the first inclined reflective portion 131 can be disposed on the first inclined pattern portion 120s1. The first flat reflective portion 132 can be connected to the first inclined reflective portion 131 and can be disposed on the first flat pattern portion 120b1. In addition, the second inclined reflective portion 133 is connected with the first flat reflective portion 132 and can be disposed on the second inclined pattern portion 120s2. The second flat reflective portion 134 is connected to the second inclined reflective portion 133 and can be disposed on the second flat pattern portion 120b2. Further, the third inclined reflective portion 135 is connected to the second flat reflective portion 134 and can be disposed on the third inclined pattern portion 120s3. Also, the third flat reflective portion 136 is connected to the third inclined reflective portion 135 and can be disposed on the third flat pattern portion 120b3.

Thus, in the display apparatus 100 according to another embodiment of the present disclosure, the inclined surface 120s of the pattern portion 120 is provided to include the first inclined pattern portion 120s1, the second inclined pattern portion 120s2, and the third inclined pattern portion 120s3. Here, the first inclined pattern portion 120s1 is provided at the first angle θ₁ with respect to the upper surface 110a of the substrate 110, and the second inclined pattern portion 120s2 is provided at the second angle θ₂, and the third inclined pattern portion 120s3 is provided at a third angle θ₃. Thus, the reflective portion 130 can include the first inclined reflective portion 131 provided at the first angle θ₁, the second inclined reflective portion 133 provided at the second angle θ₂, and the third inclined reflective portion 135 provided at the third angle θ₃. Accordingly, the display apparatus 100 according to another embodiment of the present disclosure can include the first inclined reflective portion 131, the second inclined reflective portion 133 and the third inclined reflective portion 135 provided at multiple angles, i.e., the inclined reflective portion provided in three stages enables light that is extinguished by the wave guide and light that is totally reflected and extinguished inside the substrate 110, to be output to the outside in the form of the first reflected light EL1 and the second reflected light EL2, thereby improving light extraction efficiency.

On the other hand, the display apparatus 100 according to another embodiment of the present disclosure can be provided such that the pattern portion 120 further includes a third inclined pattern portion 120s3, such that the overall horizontal length L_{T} can be increased by a horizontal length of the third inclined pattern portion 120s3. For example, the overall horizontal length L_{T} can be a horizontal length of half of the pattern portion 120, and can be the sum of the horizontal length L₁ of the first inclined pattern portion 120s1, the horizontal length L_{F1} of the first flat pattern portion 120b1 and the horizontal length L₂ of the second inclined pattern portion 120s2, the horizontal length L_{F2} of the second flat pattern portion 120b2, and the horizontal length L₃ of the third inclined pattern portion 120s3. The horizontal length L_{F2} of the second flat pattern portion 120b2 can be a horizontal length from a point where the second flat pattern portion 120b2 and the second inclined pattern portion 120s2 contact to a point where the second flat pattern portion 120b2 and the third inclined pattern portion 120s3 contact. In addition, the horizontal length L₃ of the third inclined pattern portion 120s3 can be a horizontal length from a point where the second flat pattern portion 120b2 and the third inclined pattern portion 120s3 contact to a point where the third flat pattern portion 120b3 and the third inclined pattern portion 120s3 contact.

Thus, in the display apparatus 100 in accordance with other embodiments of the present disclosure, the first reflective light EL1 can include a first sub-reflective light EL1-1 reflected from the first inclined reflective portion 131 and directed to the outside of the substrate 110, and a second sub-reflective light EL1-2 reflected from the second inclined reflective portion 133 and directed to the outside of the substrate 110. In addition, the first reflective light EL1 can further include a third sub-reflective light reflected from the third inclined reflective portion 135 and directed to the outside of the substrate 110. The second reflected light EL2 can be reflected from the third inclined reflective portion 135 and directed to the outside of the substrate 110. However, and not limited thereto, the second reflected light EL2 can be reflected from the first inclined reflective portion 131 or the second inclined reflective portion 133 and directed to the outside of the substrate 110.

Meanwhile, the overcoat layer 113 (or the third overcoat layer) on which the third inclined pattern portion 120s3 is formed can be provided to have a third thickness D3. The overcoat layer 113 (or second overcoat layer) on which the second inclined pattern portion 120s2 is formed can be provided to have the second thickness D2. The overcoat layer 113 (or the first overcoat layer) in which the first inclined pattern portion 120s1 is formed can be provided to have the first thickness D1. As shown in FIG. 7, the third thickness D3 can be provided to be equal to the first thickness D1 (or the second thickness D2), but is not necessarily limited thereto, and the third thickness D3 can be provided to be thicker or thinner than the second thickness D2 depending on the optimal design for light extraction efficiency. Further, the sum of the first thickness D1, the second thickness D2 and the third thickness D3 can be the total thickness D_{T} of the overcoat layer 113 on which the first inclined pattern portion 120s1, the second inclined pattern portion 120s2 and the third inclined pattern portion 120s3 are disposed.

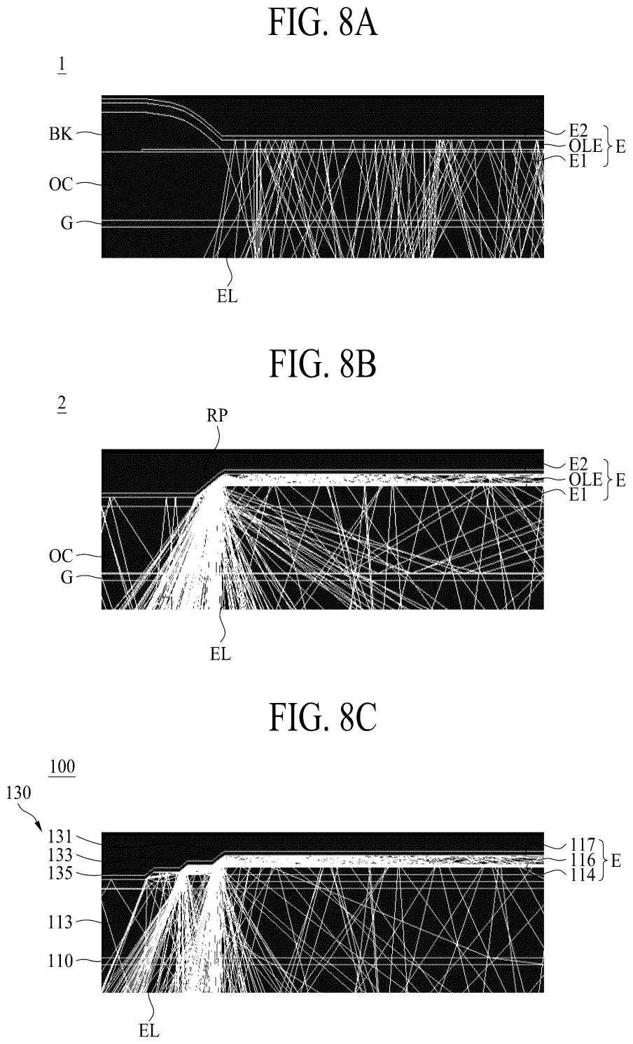

Next, FIG. 8A is an image illustrating light extraction characteristics of a display apparatus according to a comparative example, FIG. 8B is an image illustrating light extraction characteristics of a display apparatus according to another comparative example, and FIG. 8C is an image illustrating light extraction characteristics of a display apparatus according to another embodiment of the present disclosure.

In more detail, FIG. 8A is an illustration of light extraction characteristics of the display apparatus 1 according to a comparative example, in which the overcoat layer OC has a structure without an inclined surface. Specifically, in the display apparatus 1 according to the comparative example of FIG. 8A, the light emitting element layer E can include a first electrode E1, an organic light emitting layer (OLE) on the first electrode E1, and a second electrode E2 on the organic light emitting layer OLE. The bank BK covers an edge of the first electrode E1, and the organic light emitting layer OLE and the second electrode E2 can be formed on the first electrode E1 and the bank BK. Because the display apparatus 1 according to the comparative example of FIG. 8A has a structure in which the overcoat layer OC has no inclined surface, light emitted from the organic light emitting layer OLE can be reflected from the second electrode E2 and directed to the lower surface of the substrate G in the form of reflected light EL.

Next, FIG. 8B illustrates the light extraction characteristics of the display apparatus 2 according to another comparative example, in which the overcoat layer OC has a single inclined surface. Specifically, in the display apparatus 2 according to the other comparative example of FIG. 8B, the light emitting element layer E can include a first electrode E1, an organic light emitting layer (OLE) on the first electrode E1, and a second electrode E2 on the organic light emitting layer (OLE). In addition, the organic light emitting layer OLE and the second electrode E2 can be formed entirely on the overcoat layer OC along a profile of the overcoat layer OC having the single inclined surface. Because the display apparatus 2 according to the other comparative example of FIG. 8B is a structure having a single inclined surface on the overcoat layer OC without banks, a reflective surface RP that is part of the second electrode E2 can be formed on the single inclined surface. Therefore, in the display apparatus 2 according to the other comparative example of FIG. 8B, light emitted by the organic light emitting layer OLE can be reflected from the second electrode E2 and directed to the lower surface of the substrate G, or can be reflected from the reflective surface RP and directed in the form of reflected light EL.

Referring to FIGS. 8A and 8B, it can be seen that the light extraction efficiency of the display apparatus 2 according to the other comparative example of FIG. 8B is higher compared to the light extraction efficiency of the display apparatus 1 according to the comparative example of FIG. 8A. This is because the reflective surface RP reflects the light emitted from the organic light emitting layer OLE and directed to the adjacent sub-pixels, and thus, light extraction efficiency can be higher.

Next, FIG. 8C illustrates light extraction characteristics of the display apparatus 100 according to another embodiment of the present disclosure, wherein the overcoat layer OC has a structure with three inclined surfaces. As described above, the display apparatus 100 according to another embodiment of the present specification is provided with the first inclined reflective portion 131, the second inclined reflective portion 133, and the third inclined reflective portion 135, such that the reflected light EL includes reflected light that is reflected from the first inclined reflective portion 131 and directed to a lower portion of the substrate 110, reflected light that is reflected from the second inclined reflective portion 133 and directed to a lower portion of the substrate 110, and reflected light that is reflected from the third inclined reflective portion 135 and directed to a lower portion of the substrate 110. Thus, it can be seen that the display apparatus 100 according to other embodiments of the present disclosure has a higher light extraction efficiency compared to the display apparatus according to the comparative example of FIG. 8A and/or FIG. 8B.

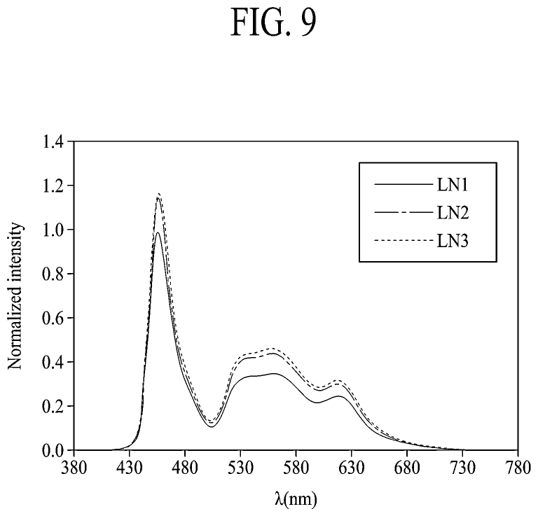

Next, FIG. 9 is a graph depicting light intensity as a function of wavelength for a display apparatus according to another embodiment of the present disclosure compared to a display apparatus according to a comparative example. Referring to FIG. 9, the horizontal axis indicates a wavelength λ, and the perpendicular axis indicates a light intensity. LN1 is a graph indicating a light intensity according to a wavelength of the display apparatus 1 according to the comparative example of FIG. 8A. In other words, LN1 is a graph indicating a light intensity according to a wavelength of the display apparatus without an inclined surface in the overcoat layer OC. LN2 is a graph showing the light intensity according to a wavelength of the display apparatus 2 according to another comparative example of FIG. 8B. That is, LN2 is a graph representing the light intensity as a function of wavelength of a display apparatus having a single inclined surface in the overcoat layer OC. LN3 is a graph representing the light intensity according to a wavelength of the display apparatus 100 according to another embodiment of the present disclosure in FIG. 8C. That is, LN3 is a graph representing the light intensity as a function of wavelength of a display apparatus having three inclined surfaces in the overcoat layer OC.

As shown in FIG. 9, it can be seen that LN3 has the highest light intensity at all wavelengths compared to LN1 and LN2. For example, it can be seen that at a blue wavelength of about 460 nm, LN1 has a light intensity of about 0.98, while LN3 has a light intensity of 1.18. Thus, the display apparatus 100 according to another embodiment of the present disclosure can have an improved light intensity of about 17% compared to the display apparatus 1 according to the comparative example at a wavelength of about 460 nm. By contrasting the areas under each of the graphs of LN1 and LN3, it can be seen that LN3 has an improved light intensity of about 27% compared to LN1. Thus, the display apparatus 100 according to another embodiment of the present disclosure is provided to have three inclined surfaces in the overcoat layer thereby having about 27% more improved light extraction efficiency compared to the display apparatus 1 having no inclined surfaces in the overcoat layer.

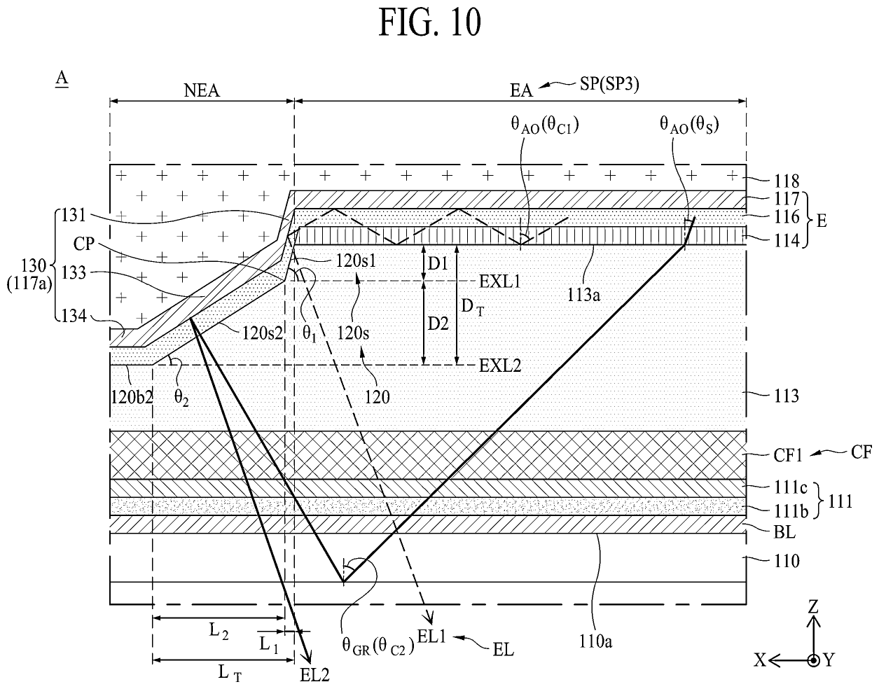

Next, FIG. 10 is a schematic enlarged cross-sectional view illustrating a display apparatus according to another embodiment of the present disclosure, as another example of the portion A shown in FIG. 3. Referring now to FIG. 10, the display apparatus 100 is similar to the display apparatus according to FIG. 1 described above, except that the structure of the pattern portion 120 and the reflective portion 130 has been changed. Therefore, the same drawing symbols have been assigned to the same configuration, and only the different configurations will be described hereinafter.

For the display apparatus according to FIG. 1 described above, the inclined surface 120s of the pattern portion 120 is provided to include the first inclined pattern portion 120s1 and the second inclined pattern portion 120s2. Here, the first inclined pattern portion 120s1 is provided at the first angle θ₁ with respect to the upper surface 110a of the substrate 110, and the second inclined pattern portion 120s2 is provided at the second angle θ₂ spaced in the first direction (X-axis direction) from the first inclined pattern portion 120s1. Thus, the reflective portion 130 can include the first inclined reflective portion 131 and the second inclined reflective portion 133, the first inclined reflective portion 131 is provided at the first angle θ₁, and the second inclined reflective portion 133 is spaced in the first direction (X-axis direction) from the first inclined reflective portion 131 and provided at the second angle θ₂. Here, the first inclined pattern portion 120s1 can be connected with the second inclined pattern portion 120s2 via the first flat pattern portion 120b1. Accordingly, for the display apparatus according to FIG. 1, the first inclined reflective portion 131 and the second inclined reflective portion 133, which are provided at multiple angles (or equal angles), i.e., the inclined reflective portion provided in two stages enable light that is extinguished by the wave guide and light that is totally reflected and extinguished inside the substrate, to be output to the outside in the form of the first reflected light EL1 and the second reflected light EL2, thereby improving light extraction efficiency.

In contrast, in the display apparatus according to FIG. 10, the first angle θ₁ and the second angle θ₂ are different, and the first inclined pattern portion 120s1 can be directly connected with the second inclined pattern portion 120s2. In other words, the display apparatus according to FIG. 10 can be provided with a structure in which the first angle θ₁ and the second angle θ₂ are different from the display apparatus according to FIG. 1, and the first flat pattern portion 120b1 connecting the first inclined pattern portion 120s1 and the second inclined pattern portion 120s2 is deleted (or omitted). When the first angle θ₁ and the second angle θ₂ are the same, the first inclined pattern portion 120s1 and the second inclined pattern portion 120s2 are provided as a single inclined surface without a bent, thus one of the light that is extinguished by the wave guide and the light that is totally reflected and extinguished in the interior of the substrate 110 may not be extracted to the exterior of the substrate 110 through the first inclined reflective portion 131 disposed on the first inclined pattern portion 120s1 and the second inclined reflective portion 133 disposed on the second inclined pattern portion 120s2.

Thus, for the display apparatus 100 according to FIG. 10, because the first angle θ₁ and the second angle θ₂ are different, the first inclined reflective portion 131 disposed on the first inclined pattern portion 120s1 and the second inclined reflective portion 133 disposed on the second inclined pattern portion 120s2 can be disposed at different angles with respect to the upper surface 110a of the substrate 110, as a result, both the light that is extinguished by the wave guide and the light that is totally reflected and extinguished from the interior of the substrate 110 can be extracted to the exterior of the substrate 110 through the first inclined reflective portion 131 and the second inclined reflective portion 133, thereby improving light extraction efficiency.

On the other hand, as shown in FIG. 10, the first angle θ₁ can be larger than the second angle θ₂. However, without being limited thereto, the first angle θ₁ can be provided to be smaller than the second angle θ₂ if both the light that is extinguished by the wave guide and the light that is totally reflected and extinguished from the interior of the substrate 110 can be extracted to the exterior of the substrate 110.

The display apparatus 100 according to FIG. 10 can further include a connection point CP connecting the first inclined pattern portion 120s1 and the second inclined pattern portion 120s2, because the first angle θ₁ and the second angle θ₂ are different. As shown in FIG. 10, the pattern portions 120 are formed in the non-light emission area NEA, therefore the connection points CP can be disposed in the non-light emission area NEA. The display apparatus 100 according to FIG. 10 can have a structural feature in which the first inclined pattern portion 120s1 is directly connected with the second inclined pattern portion 120s2 at the connection point CP, so that the second inclined reflective portion 133 disposed on the second inclined pattern portion 120s2 and the first inclined reflective portion 131 disposed on the first inclined pattern portion 120s1 are directly connected.

On the other hand, in the display apparatus 100 according to FIG. 10, because the first inclined pattern portion 120s1 is directly connected with the second inclined pattern portion 120s2 at the connection point CP, the overall horizontal length L_{T} from the point where the second inclined pattern portion 120s2 and the second flat pattern portion 120b2 contact to the end of the light emission area EA can be further reduced compared to the display apparatus according to FIG. 1. For example, the overall horizontal length L_{T} can be a length that is the sum of the horizontal length L₁ of the first inclined pattern portion 120s1 and the horizontal length L₂ of the second inclined pattern portion 120s2. Thus, the second inclined pattern portion 120s2 can be disposed closer to the light emission area EA in the horizontal direction (or the first direction (X-axis direction)).

By disposing the second inclined pattern portion 120s2 closer to the light emission area EA in the horizontal direction (or the first direction (X-axis direction)), the second inclined reflective portion 133 disposed on the second inclined pattern portion 120s2 can also be disposed closer to the light emission area EA. Thus, the display apparatus 100 according to another embodiment of the present disclosure can have the second inclined reflective portion 133 disposed closer to the light emission area EA, therefore the loss amount of light emitted by the organic light emitting layer 116 and reaching the second inclined reflective portion 133, is minimized. For example, while light emitted by the organic light emitting layer 116 passes through a plurality of layers (e.g., the overcoat layer 113, the color filter CF, the inorganic film layer 111) in the substrate to reach the second inclined reflective portion 133, the loss of the light can be occurred. However, the display apparatus 100 according to another embodiment of the present disclosure can be provided such that the second inclined reflective portion 133 is disposed close to the light emission area EA, such that the light loss to reach the second inclined reflective portion 133 can be minimized, thereby maximizing the light extraction efficiency of the substrate 110 to the outside.

In addition, the present disclosure has described a display apparatus 100 including the first inclined pattern portion 120s1 (or the first inclined reflective portion 131) having the first angle θ₁, the second inclined pattern portion 120s2 (or the second inclined reflective portion 133) having the second angle θ₂, and the third inclined pattern portion 120s3 (or the third inclined reflective portion 135) having a third angle θ₃ have been described, but the number and optimal extent (or optimal horizontal length and optimal thickness) of the inclined pattern portions (or the inclined reflective portions) can be varied depending on the refractive index and design of the material. Here, the material can be meant to include at least one of the materials of the overcoat layer 113, the material of the organic light emitting layer 116, the material of the pixel electrode 114, the material of the reflective electrode 117 (or the reflective portion 130), and the material of the substrate 110.

The display apparatus according to the present disclosure is provided to have the reflective portion disposed on the pattern portion that is formed to be concave between the plurality of sub-pixels, so that light directed at the adjacent sub-pixels can be reflected from the reflective portion, thereby improving light extraction efficiency. Because the display apparatus according to the present disclosure can have light extraction even in the non-light emission area through the reflective portion, it can have the same light extraction efficiency or even better light extraction efficiency with lower power compared to a display apparatus without the reflective portion, thereby reducing overall power consumption.

In the display apparatus according to the present disclosure, the inclined surface of the pattern portion is provided at multiple angles (the first angle and the second angle) with respect to the upper surface of the substrate, so that light extraction efficiency can be maximized as both the light that is extinguished by the wave guide and the light that is totally reflected and extinguished inside the substrate can be directed to the outside.

The effects to be obtained from the present disclosure are not limited to those mentioned above, and other effects not mentioned will be apparent to one of ordinary skill in the art from the description.

Embodiments of the present disclosure have been described in more detail with reference to the accompanying drawings, but the present disclosure is not necessarily limited to these embodiments and can be practiced in various modifications without departing from the technical ideas of the present disclosure. Accordingly, the embodiments disclosed herein are intended to illustrate, not limit, the technical ideas of the present disclosure, and the scope of the technical ideas of the present disclosure is not limited by these embodiments. Therefore, the embodiments described above are exemplary in all respects and should be understood as non-limiting. All technical ideas within the scope of protection of this specification shall be construed to be included within the scope of the claims of this specification.

What is claimed is:

1. A display apparatus comprising:
a substrate including a plurality of pixels, each pixel having a plurality of sub-pixels and non-light emission areas between the sub-pixels;
a pattern portion disposed on the substrate; and
a reflective portion disposed on the pattern portion,
wherein the pattern portion includes:
a first inclined pattern portion inclining at a first angle with respect to an upper surface of the substrate; and
a second inclined pattern portion inclining at a second angle with respect to the upper surface of the substrate, and
wherein the reflective portion includes:
a first inclined reflective portion disposed on the first inclined pattern portion; and
a second inclined reflective portion disposed on the second inclined pattern portion.

2. The display apparatus of claim 1, wherein the first angle is equal to or different from the second angle.

3. The display apparatus of claim 1, wherein the pattern portion further includes:
a first flat pattern portion connecting the first inclined pattern portion and the second inclined pattern portion; and
a second flat pattern portion connected to the second inclined pattern portion, and
wherein the reflective portion further includes:
a first flat reflective portion connected to the first inclined reflective portion and disposed on the first flat pattern portion; and
a second flat reflective portion connected to the second inclined reflective portion and disposed on the second flat pattern portion.

4. The display apparatus of claim 1, wherein a width of the pattern portion decreases in a direction from the reflective portion toward the substrate.

5. The display apparatus of claim 1, wherein each sub-pixel includes a light emission area disposed adjacent to the non-light emission area,
wherein the non-light emission area includes a circuit area disposed on one side of the light emission area, and
wherein the pattern portion surrounds a remainder of the light emission area except for the one side of the light emission area on which the circuit area is disposed.

6. The display apparatus of claim 1, further comprising:
an overcoat layer disposed on the substrate,
wherein the pattern portion is disposed on the overcoat layer,
wherein each sub-pixel includes a pixel electrode disposed on the overcoat layer,
wherein the first inclined pattern portion is disposed adjacent to the pixel electrode, and
wherein the second inclined pattern portion is spaced apart from the pixel electrode.

7. The display apparatus of claim 6, further comprising:
an organic light emitting layer disposed on the pixel electrode; and
a reflective electrode on the organic light emitting layer,
wherein the reflective portion includes the reflective electrode, and
wherein θ₁ denotes the first angle and is defined as:
$${θ}_{1} > 90 ° - {θ}_{c 1}$$
where θ_{c1} denotes an angle at which a portion of light emitted by the organic light emitting layer is totally reflected between the pixel electrode and the overcoat layer.

8. The display apparatus of claim 7, wherein θ_{c1} is defined as:
$${θ}_{c 1} = arcsin ( \frac{{n}_{oc}}{{n}_{Andoe}} )$$
where n_{oc} denotes a refractive index of the overcoat layer, and n_{Anode} denotes a refractive index of the pixel electrode.

9. The display apparatus of claim 8, wherein when a portion of light emitted by the organic light emitting layer is not emitted to the outside of the substrate and is trapped inside the substrate, an angle θₛ of the portion of light incident on an interface between the pixel electrode and the overcoat layer is defined as:
$$270 ° - 2 {θ}_{1} - {θ}_{c 1} > {θ}_{S} .$$

10. The display apparatus of claim 7, wherein the first angle θ₁ is further defined as:
$${θ}_{1} < 135 ° - 0.5 arcsin ( \frac{{n}_{oc}}{{n}_{Andoe}} ) - 0.5 arcsin ( \frac{{n}_{oc}}{{n}_{Andoe}} sin ( arcsin ( \frac{1}{{n}_{oc}} ) ) )$$
where n_{oc} denotes a refractive index of the overcoat layer, and n_{Anode} denotes a refractive index of the pixel electrode.

11. The display apparatus of claim 7, wherein θ₂ denotes the second angle and is defined as:
$${θ}_{2} < arcsin ( \frac{{n}_{air}}{{n}_{oc}} )$$
where n_{oc} denotes a refractive index of the overcoat layer, and nₐᵢᵣ denotes the refractive index of outside air.

12. The display apparatus of claim 3, wherein the pattern portion further comprises:
a third inclined pattern portion disposed between the second inclined pattern portion and the substrate and inclining at a third angle with respect to the upper surface of the substrate; and
a third flat pattern portion spaced apart from the second flat pattern portion and connected to the third inclined pattern portion, and
wherein the reflective portion further comprises:
a third inclined reflective portion connected to the second flat reflective portion and disposed on the third inclined pattern portion; and
a third flat reflective portion connected to the third inclined reflective portion and disposed on the third flat pattern portion.

13. The display apparatus of claim 12, wherein the third angle is equal to or different from the second angle.

14. The display apparatus of claim 1, wherein the first angle and the second angle are different, and
wherein the first inclined pattern portion is directly connected to the second inclined pattern portion.

15. The display apparatus of claim 14, further comprising:
a connection point connecting the first inclined pattern portion and the second inclined pattern portion,
wherein the connection point is disposed in the non-light emission area.

16. A display apparatus comprising:
a substrate including light emission areas corresponding to a plurality of sub-pixels included in each pixel, and including non-light emission areas between adjacent sub-pixels;
a reflective portion disposed in the non-light emission areas and the light emission areas and configured to reflect light emitted by a corresponding sub-pixel,
wherein the reflective portion includes:
a flat reflective portion in the light emission area and corresponding to a reflective electrode on a pixel electrode of the corresponding sub-pixel;
a first inclined reflective portion in the non-light emission area and connected to the flat reflective portion, the first inclined reflective portion inclining at a first angle with respect to a surface of the substrate; and
a second inclined reflective portion in the non-light emission area and connected to the first inclined reflective portion, the second inclined reflective portion inclining at a second angle with respect to the surface of the substrate,
wherein a first light emitted from the corresponding sub-pixel is waveguided within the corresponding sub-pixel and reflected by the first inclined reflective portion to an outside of the substrate, and
wherein a second light emitted from the corresponding sub-pixel is emitted toward the substrate and reflected from a lower surface of the substrate back to the second inclined reflective portion and then reflected to the outside of the substrate.

17. The display apparatus of claim 16, wherein the first angle is greater than the second angle.

18. The display apparatus of claim 16, wherein the flat reflective portion connects the first inclined reflective portion and the second inclined reflective.

19. The display apparatus of claim 16, wherein the second angle is set such that an angle of the light reflected by the second inclined reflective portion passes through the substrate to the outside of the substrate.

20. The display apparatus of claim 16, wherein a length of the second inclined reflective portion is greater than a length of the first inclined reflective portion.
